(19) United States
(12) Patent Application Publication
(10) Pub. No.: US 2025/0393402 A1
(43) Pub. Date: Dec. 25, 2025

(54) DISPLAY DEVICE, METHOD OF MANUFACTURING THE SAME, AND ELECTRONIC DEVICE INCLUDING THE SAME

(71) Applicant: SAMSUNG DISPLAY CO., LTD., YONGIN-SI (KR)

(72) Inventors: YEEUN KANG, Yongin-si (KR); SEUL-KI KIM, Yongin-si (KR); HYUN KIM, Yongin-si (KR); JEONGJU PARK, Yongin-si (KR); JIN-WON LEE, Yongin-si (KR)

(21) Appl. No.: 19/073,945

(22) Filed: Mar. 7, 2025

(30) Foreign Application Priority Data
Jun. 24, 2024 (KR) 10-2024-0082201

(51) Int. Cl. H10K 59/122; H10K 59/12; H10K 59/124

(52) U.S. Cl. CPC H10K 59/122; H10K 59/1201; H10K 59/124

(57) ABSTRACT

A display device including a via insulating layer disposed on a substrate, a first light emitting element including a first pixel electrode disposed on the via insulating layer, a second light emitting element including a second pixel electrode disposed on the via insulating layer, wherein the second pixel electrode is spaced apart from the first pixel electrode by at least a first distance to form a first non-pixel electrode area, a third light emitting element including a third pixel electrode disposed on the via insulating layer, wherein the third pixel electrode is spaced apart from the first pixel electrode by a second distance to form a second non-pixel electrode area, a first pixel defining layer disposed in the first non-pixel electrode area on the via insulating layer, and a second pixel defining layer disposed in the second non-pixel electrode area on the via insulating layer.

### CROSS-REFERENCE TO RELATED APPLICATION(S)

This U.S. non-provisional patent application claims priority under 35 U.S.C. § 119 to Korean Patent Application No. 10-2024-0082201, filed on Jun. 24, 2024, in the Korean Intellectual Property Office (KIPO), the entire disclosure of which is incorporated by reference in its entirety.

### BACKGROUND

### 1. Field

Embodiments of the present disclosure relate to a display device and a method of manufacturing the display device. More specifically, embodiments of the present disclosure relate to a display device that provides visual information and a method of manufacturing the display device. Embodiments of the present disclosure relate to an electronic device including a display device that provides visual information and a method of manufacturing the electronic device.

### 2. Description of the Related Art

A display device is formed by stacking a plurality of layers including a metal layer, an insulating layer, a light emitting layer, or the like. Some layers of the plurality of layers may be provided in common to a plurality of pixels. When some layers provided in common to the plurality of pixels function as a charge transfer path, current supplied to one pixel may be supplied to another adjacent pixel, and as a result, a leakage current may be generated. Due to this leakage current, pixels of different colors adjacent to each other may be driven to generate color mixing.

### SUMMARY

Embodiments provide a display device with improved display quality. Embodiments provide a method of manufacturing the display device. Embodiments provide an electronic device including the display device.

A display device according to an embodiment of the present disclosure includes a via insulating layer disposed on a substrate, a first light emitting element disposed on the via insulating layer, wherein the first light emitting element includes a first pixel electrode, a second light emitting element disposed on the via insulating layer, wherein the second light emitting element includes a second pixel electrode, and wherein a second pixel electrode spaced apart from the first pixel electrode by at least a first distance to form a first non-pixel electrode area having at least the first distance, a third light emitting element disposed on the via insulating layer, wherein the third light emitting element includes a third pixel electrode, wherein the third pixel electrode is spaced apart from the first pixel electrode by a second distance to form the non-pixel electrode area of the second distance, a first pixel defining layer disposed in the first non-pixel electrode area on the via insulating layer, and a second pixel defining layer disposed in the non-pixel electrode area on the via insulating layer, wherein the second pixel defining layer has a cross-sectional shape different from a cross-sectional shape of the first pixel defining layer.

In an embodiment, the second distance may be greater than or equal to the first distance. In an embodiment, the first distance is between about 4 micrometers and about 10 micrometers.

In an embodiment, the first pixel defining layer includes a groove between a lower surface of the first pixel defining layer and an upper surface of each of the first pixel electrode and the second pixel electrode. In an embodiment, the display device may further include a sacrificial pattern disposed in the groove.

In an embodiment, an upper portion of the first pixel defining layer may be spaced apart from an upper surface of the first pixel electrode and an upper surface of the second pixel electrode, and an upper portion of the second pixel defining layer may be in contact with the upper surface of the first pixel electrode and an upper surface of the third pixel electrode. In an embodiment, the first pixel defining layer may have an undercut shape in a cross-sectional view.

In an embodiment, each of the first light emitting element, the second light emitting element, and the third light emitting element may further include an intermediate layer disposed on the first pixel defining layer or the second pixel defining layer, wherein the intermediate layer includes a charge generation layer. In an embodiment, a first portion of the intermediate layer and a second portion of the intermediate layer are disconnected by the first pixel defining layer. In an embodiment, an upper surface of the via insulating layer may be recessed toward a lower surface of the via insulating layer in the first non-pixel electrode area and the second non-pixel electrode area.

A method of manufacturing a display device according to an embodiment of the present disclosure includes forming a preliminary via insulating layer on a substrate, forming a first pixel electrode, a second pixel electrode spaced apart from the first pixel electrode by at least a first distance to form a first non-pixel electrode area having at least the first distance, and a third pixel electrode spaced apart from the first pixel electrode by a second distance to form a second non-pixel electrode area having the second distance, forming a first pixel defining layer in the first non-pixel electrode area, and forming a second pixel defining layer in the second non-pixel electrode area, wherein the second pixel defining layer has a cross-sectional shape different from a cross-sectional shape of the first pixel defining layer.

In an embodiment, the second distance is greater than or equal to the first distance. In an embodiment, the first distance is between about 4 micrometers and about 10 micrometers. In an embodiment, the forming of the first pixel electrode, the second pixel electrode, and the third pixel electrode may include forming a pixel electrode layer on the preliminary via insulating layer, forming a sacrificial layer on the pixel electrode layer, forming a first photoresist pattern on the sacrificial layer, and patterning the pixel electrode layer and the sacrificial layer using the first photoresist pattern to form the first pixel electrode, the second pixel electrode, the third pixel electrode, and a sacrificial pattern.

In an embodiment, in the forming of the first photoresist pattern, the first photoresist pattern may be formed using a half-tone mask. In an embodiment, the method further includes forming a full-tone area of the first photoresist pattern to have a first thickness, and forming a half-tone area of the first photoresist pattern to have a second thickness, wherein an area adjacent to the first non-pixel electrode area is the full-tone area, an area adjacent to the second non-pixel electrode area is the half-tone area.

In an embodiment, before the forming of the first pixel defining layer and the forming of the second pixel defining layer, the method may further include removing the first photoresist pattern at least by the second thickness to form a second photoresist pattern in the full-tone area, removing at least a portion of the preliminary via insulating layer in the first non-pixel electrode area and the second non-pixel electrode area to form a via insulating layer, and removing a portion of the sacrificial pattern in the half-tone area using the second photoresist pattern.

In an embodiment, in the forming of the first pixel defining layer, the first pixel defining layer may be formed to be in contact with an upper surface of the sacrificial pattern in the full-tone area, and in the forming of the second pixel defining layer, the second pixel defining layer may be formed to be in contact with a portion of an upper surface of the first pixel electrode and a portion of an upper surface of the third pixel electrode in the half-tone area.

In an embodiment, after the forming of the first pixel defining layer and the forming of the second pixel defining layer, the method may further include removing at least a portion of the sacrificial pattern in the full-tone area to form a groove between a lower surface of the first pixel defining layer and an upper surface of the first pixel electrode and an upper surface of the second pixel electrode.

In an embodiment, the method may further include forming an intermediate layer on the first pixel defining layer and the second pixel defining layer, and a first portion of the intermediate layer and a second portion of the intermediate layer are disconnected by the first pixel defining layer.

An electronic device including a display device, wherein the display device includes a via insulating layer disposed on a substrate; a first light emitting element disposed on the via insulating layer, wherein the first light emitting element includes a first pixel electrode; a second light emitting element disposed on the via insulating layer, wherein the second light emitting element includes a second pixel electrode, and wherein the second pixel electrode is spaced apart from the first pixel electrode by at least a first distance to form a first non-pixel electrode area having at least the first distance; a third light emitting element disposed on the via insulating layer, wherein the third light emitting element includes a third pixel electrode, and wherein the third pixel electrode is spaced apart from the first pixel electrode by a second distance to form a second non-pixel electrode area having at least the second distance; a first pixel defining layer disposed in the first non-pixel electrode area on the via insulating layer; and a second pixel defining layer disposed in the second non-pixel electrode area on the via insulating layer, wherein the second pixel defining layer has a cross-sectional shape different from a cross-sectional shape of the first pixel defining layer.

In a display device according to embodiments of the present disclosure, the display device may include a first pixel defining layer disposed on pixel electrodes spaced apart by a first distance among pixel electrodes adjacent to each other and a second pixel defining layer disposed on pixel electrodes spaced apart by a second distance among pixel electrodes adjacent to each other. The first pixel defining layer may define a groove, and an intermediate layer disposed on the pixel electrodes and the first and second pixel defining layers may be disconnected by a shape (e.g., an undercut shape) of the first pixel defining layer. Accordingly, leakage current that may occur between adjacent light emitting elements may be minimized, and color mixing between the light emitting elements may be minimized. In addition, the shape of the first pixel defining layer may be formed through a photoresist pattern formed using a half-tone mask, and a process using a separate mask for forming a structure that disconnects the intermediate layer may not be required.

### BRIEF DESCRIPTION OF THE DRAWINGS

FIG. 1 is a plan view illustrating a display device according to an embodiment of the present disclosure.

FIG. 2 is an example of a plan view schematically illustrating a portion of a display area of the display device of FIG. 1.

FIG. 3 is an example of a cross-sectional view taken along line I-I′ of FIG. 2.

FIG. 4 is an example of a cross-sectional view illustrating an intermediate layer included in the display device of FIG. 1.

FIGS. 5, 6, 7, 8, 9, 10, 11, and 12 are views illustrating a method for manufacturing a display device according to an embodiment of the present disclosure.

FIG. 13 is a plan view schematically illustrating a portion of a display area of a display device according to an embodiment of the present disclosure.

FIG. 14 is an example of a cross-sectional view taken along line II-II′ of FIG. 13.

FIGS. 15, 16, 17, 18, and 19 are views illustrating a method for manufacturing a display device according to an embodiment of the present disclosure.

FIG. 20 is a block diagram illustrating an electronic device according an embodiment of the present disclosure.

FIG. 21 is a schematic view illustrating electronic devices according to embodiments of the present disclosure.

### DETAILED DESCRIPTION OF THE EMBODIMENTS

Hereinafter, embodiments of the present disclosure are described in more detail with reference to the accompanying drawings. The same reference numerals are used for the same components in the drawings, and redundant descriptions of the same components may be omitted.

It will also be understood that when a layer is referred to as being “on” or “under” another layer or substrate, it can be directly on the other layer or substrate, or intervening layers may also be present. For example, when the disclosure describes a first layer disposed on a second layer, then the first layer may be directly disposed on the second layer. In some cases, for example, a third layer may be disposed between the first layer and the second layer. In some aspects, the same reference numbers indicate the same components throughout the specification.

It will be understood that, although the terms “first,” “second,” etc. may be used herein to describe various elements, these elements should not be limited by these terms. These terms are only used to distinguish one element from another element. For example, a first element discussed below could be termed a second element without departing from the teachings and spirit of the present disclosure. Similarly, the second element could also be termed the first element.

Each of the features of the various embodiments of the present disclosure may be combined with each other, partially or fully, allowing for various technically interlocking and driving possibilities. Each embodiment may be implemented independently of each other or may be implemented together in an association.

Embodiments of the present disclosure provides an electronic device including a display device that includes a pixel defining layer disposed between a plurality of pixel electrodes to prevent current leakage from a first pixel electrode to a second pixel electrode. In some embodiments, the display device includes a first pixel electrode and a second pixel electrode disposed adjacent to a side surface of the first pixel electrode, where the first pixel electrode and the second pixel electrode are separated by a first pixel defining layer having a first width. The display device also includes a second third pixel electrode disposed adjacent to an opposite side surface of the first pixel electrode, wherein the first pixel electrode and the third pixel electrode are separated by a second pixel defining layer having a second width. In some cases, the intermediate layer disposed on the first pixel electrode and the second pixel electrode may be disconnected. Accordingly, the configuration of the pixel electrodes, the intermediate layer, and the pixel defining layers of the display device of the present disclosure can effectively minimize current leakage between the adjacent light emitting elements (e.g., the pixel electrodes). In some cases, color mixing between the adjacent light emitting elements can be reduced.

In some embodiments, an intermediate layer is disposed on the plurality of the pixel electrodes (e.g., the first pixel electrode, the second pixel electrode, and the third pixel electrode). In some embodiments, the pixel defining layers (e.g., the first pixel defining layer or the second pixel defining layer) are formed to have an undercut shape. Conventionally, a separate process using a separate mask may be required to form the structure that disconnects the intermediate layer of the display device. However, the shape of the first pixel defining layer can be formed through a photoresist pattern using a half-tone mask. Accordingly, without the need to use the additional pattern forming process, the efficiency in manufacturing the display device can be increased.

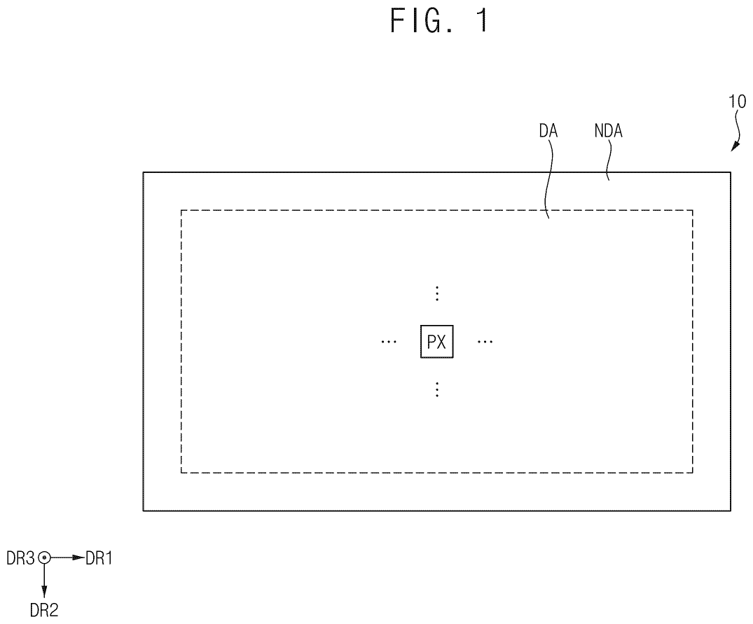

FIG. 1 is a plan view illustrating a display device according to an embodiment of the present disclosure. Referring to FIG. 1, the example shown includes a display device 10 including a display area DA and a non-display area NDA.

The display area DA may be an area that displays an image. In some cases, the display area DA may be an area that includes information or data to be presented for viewing. In the display area DA, a plurality of pixels PX may be disposed along a first direction DR1 and a second direction DR2 intersecting the first direction DR1. For example, the second direction DR2 may be perpendicular to the first direction DR1. Each of the pixels PX may include a pixel circuit and a light emitting element. In some cases, each of the pixels PX may emit light. Accordingly, for example, an image may be displayed in a third direction DR3 intersecting each of the first direction DR1 and the second direction DR2 in the display area DA. For example, the third direction DR3 may be perpendicular to both of the first direction DR1 and the second direction DR2.

Signal lines such as a gate line, a data line, or the like may be further disposed in the display area DA. The signal lines may be connected to the pixels PX, respectively. The signal lines may provide gate signal, data signal, or the like to the pixels PX.

The non-display area NDA may be an area that does not display an image. In some cases, the non-display area NDA may be an area that does not include information or data to be presented for viewing. The non-display area NDA may be disposed around the display area DA. For example, the non-display area NDA may surround the display area DA in a plan view. Drivers for displaying an image in the display area DA may be disposed in the non-display area NDA.

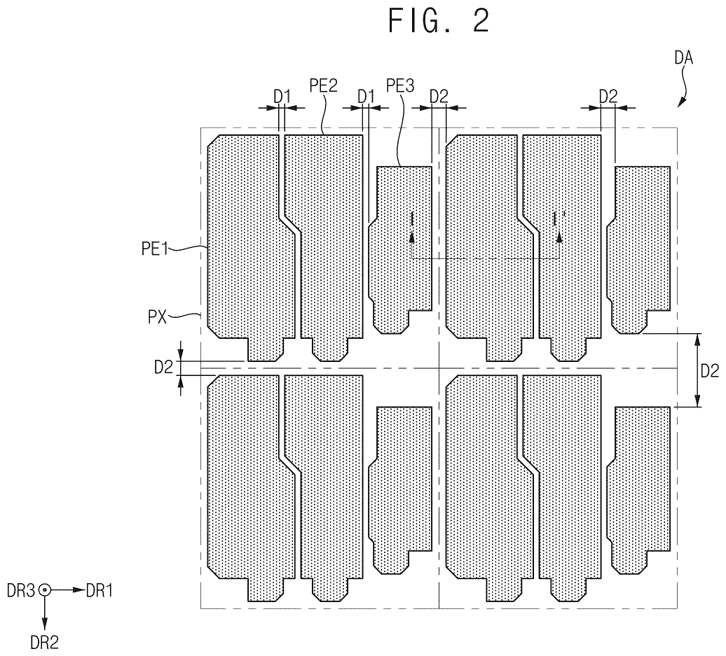

FIG. 2 is an example of a plan view schematically illustrating a portion of a display area of the display device of FIG. 1. FIG. 2 may be a plan view illustrating first, second, and third pixel electrodes PE1, PE2, and PE3, respectively, included in each of four pixels PX disposed in a matrix of two rows and two columns among the pixels PX disposed in the display area DA of the display device 10. However, the number of pixels included in the pixel group should not be limited to the example shown in FIG. 2.

Referring to FIG. 2, the pixels PX may be disposed in the first direction DR1 and the second direction DR2 in the display area DA. Each of the pixels PX may include the first pixel electrode PE1, the second pixel electrode PE2, and the third pixel electrode PE3. For example, each of the first, second, and third pixel electrodes PE1, PE2, and PE3 may function as an anode of the light emitting element.

In each of the pixels PX, the first, second, and third pixel electrodes PE1, PE2, and PE3 may be adjacent to each other. For example, in each of the pixels PX, the second pixel electrode PE2 may be adjacent to the first pixel electrode PE1 in the first direction DR1, and the third pixel electrode PE3 may be adjacent to the second pixel electrode PE2 in the first direction DR1. For example, the second pixel electrode PE2 may be disposed between the first pixel electrode PE1 and the third pixel electrode PE3 in the first direction DR1. However, the present disclosure is not limited thereto, and the arrangement of the first, second, and third pixel electrodes PE1, PE2, and PE3 may be variously changed. In some cases, the third pixel electrode PE3 of a first pixel of the pixels PX may be disposed adjacent to a first pixel electrode PE1 of a second pixel of the pixels PX in the first direction. In some embodiments, the configuration of the first pixel may be the same as the configuration of the third pixel disposed adjacent to the first pixel in the second direction DR2.

In each of the pixels PX, the first pixel electrode PE1, second pixel electrode PE2, and third pixel electrode PE3 adjacent to each other may be spaced apart from each other by a first distance D1 or a second distance D2 in a plan view. In an embodiment, the second distance D2 may be greater than or equal to the first distance D1. For example, the second distance D2 may be a value relatively greater than the first distance D1. For example, in each of the pixels PX, the first pixel electrode PE1, second pixel electrode PE2, and third pixel electrode PE3 may be spaced apart from each other by at least the first distance D1 in the first direction DR1.

In each of the pixels PX, the first pixel electrode PE1 and the second pixel electrode PE2 may be spaced apart by least the first distance D1. For example, in each of the pixels PX, a portion of the first pixel electrode PE1 and a portion of the second pixel electrode PE2 may be spaced apart by the first distance D1 in the first direction DR1, and another portion of the first pixel electrode PE1 and another portion of the second pixel electrode PE2 may be spaced apart by the second distance D2 in the first direction DR1.

In some cases, in each of the pixels PX, the second pixel electrode PE2 and the third pixel electrode PE3 may be spaced apart at least a first distance D1. For example, in each of the pixels PX, a portion of the second pixel electrode PE2 and a portion of the third pixel electrode PE3 may be spaced apart by the first distance D1 in the first direction DR1, and another portion of the second pixel electrode PE2 and another portion of the third pixel electrode PE3 may be spaced apart by the second distance D2 in the first direction DR1.

Pixel electrodes, which are included in different adjacent pixels PX and are most adjacent to each other, may be spaced apart from each other by the second distance D2 in a plan view. For example, in the pixels PX adjacent to each other in the first direction DR1, the third pixel electrode PE3 of a first pixel PX and the first pixel electrode PE1 of a second pixel PX adjacent to the first pixel PX in the first direction DR1 may be spaced apart by the second distance D2 in the first direction DR1. For example, in the pixels PX adjacent to each other in the second direction DR2, the first, second, and third pixel electrodes PE1, PE2, and PE3 of a first pixel PX and the first, second, and third pixel electrodes PE1, PE2, and PE3 of a third pixel PX adjacent to the first pixel PX in the second direction DR2 may be spaced apart by the second distance D2 in the second direction DR2, respectively. In some cases, the second distance D2 between the third pixel electrode PE3 of the first pixel and third pixel electrode PE3 of the third pixel in the second direction DR2 may be greater than the second distance D2 between the first pixel electrode PE1 of the first pixel and first pixel electrode PE1 of the third pixel in the second direction DR2.

In an embodiment, the first distance D1 and the second distance D2 may be a predetermined value. For example, the first distance D1 may be a value less than or equal to the predetermined value, and the second distance D2 may be a value greater than or equal to the predetermined value. For example, when the separation distance between adjacent pixel electrodes among the first, second, and third pixel electrodes PE1, PE2, and PE3 is less than or equal to the predetermined value, the pixel electrodes may be spaced apart by the first distance D1. For example, when the separation distance between adjacent pixel electrodes among the first, second, and third pixel electrodes PE1, PE2, and PE3 is greater than or equal to the predetermined value, the pixel electrodes may be spaced apart by the second distance D2.

For example, the predetermined value may be about 10 micrometers (μm). The first distance D1 may be a value of about 10 μm or less, and the second distance D2 may be a value of about 10 μm or more. For example, the first distance D1 may be between about 4 μm and about 10 μm, and the second distance D2 may be about 10 μm or more. However, the present disclosure is not limited thereto, and the predetermined value may be variously changed based on a separation distance between pixels PX, a size of the pixels PX, or the like.

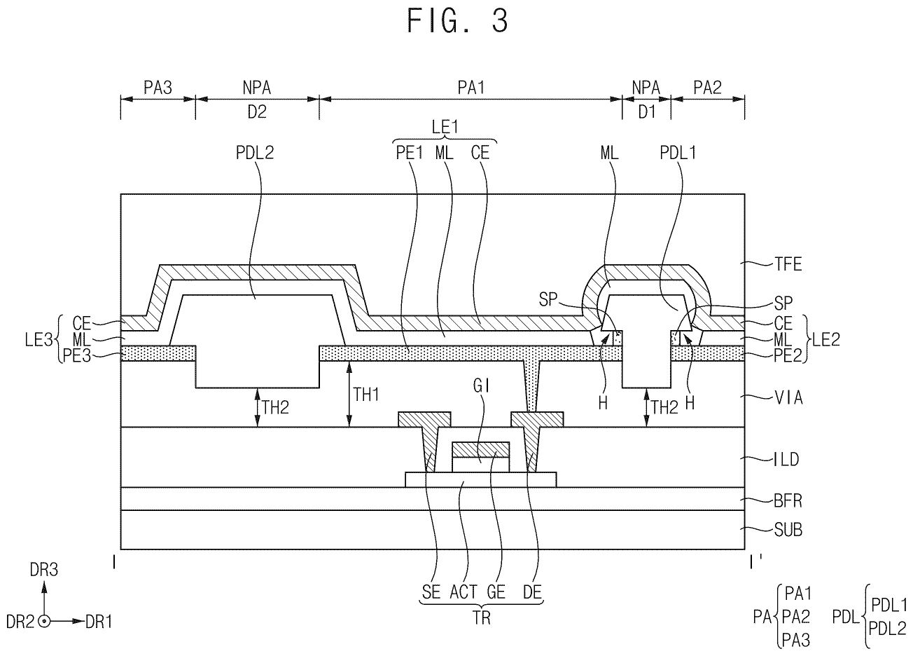

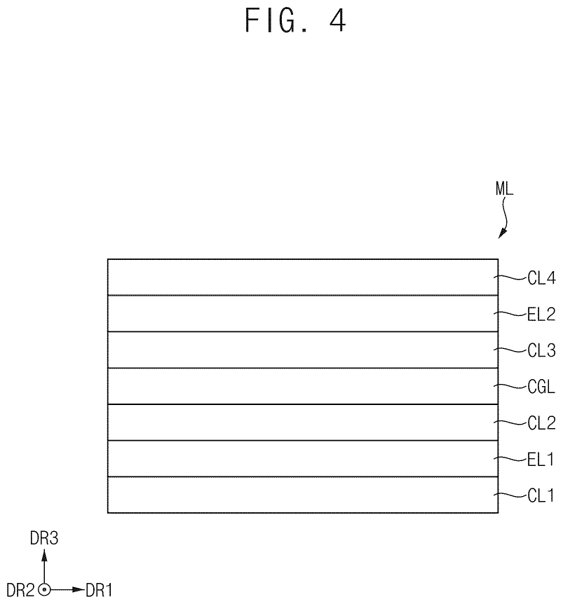

FIG. 3 an example of is a cross-sectional view taken along line I-I′ of FIG. 2. FIG. 4 is an example of a cross-sectional view illustrating an intermediate layer included in the display device of FIG. 1.

Referring to FIGS. 2, 3, and 4, the display device 10 may include a substrate SUB, a buffer layer BFR, a transistor TR, a gate insulating layer GI, an interlayer insulating layer ILD, a via insulating layer VIA, a first light emitting element LE1, a second light emitting element LE2, a third light emitting element LE3, a pixel defining layer PDL, and an encapsulation layer TFE. In some aspects, the transistor TR may include an active pattern ACT, a gate electrode GE, a first electrode SE, and a second electrode DE. In some aspects, each of the first light emitting element LE1, the second light emitting element LE2, and the third light emitting element LE3 includes a common electrode CE, an intermediate layer ML, and a pixel electrode PE (e.g., a first pixel electrode PE1, a second pixel electrode PE2, or a third pixel electrode PE3).

The transistor TR may include an active pattern ACT, a gate electrode GE, a first electrode SE, and a second electrode DE. The first light emitting element LE1 may include a first pixel electrode PE1, an intermediate layer ML, and a common electrode CE, the second light emitting element LE2 may include a second pixel electrode PE2, the intermediate layer ML, and the common electrode CE, and the third light emitting element LE3 may include a third pixel electrode PE3, the intermediate layer ML, and the common electrode CE.

The substrate SUB may include a transparent material or an opaque material. Examples of materials that may be used as the substrate SUB may include glass, quartz, polymer, silicon, or the like. In some cases, the materials may be used independently or in combination with each other.

The buffer layer BFR may be disposed on the substrate SUB. The buffer layer BFR may prevent metal atoms, impurities, or the like from diffusing into the transistor TR. The buffer layer BFR may include an inorganic material such as silicon oxide (SiOₓ), silicon nitride (SiNₓ), silicon oxynitride (SiOₓN_{y}), or the like. In some cases, these materials may be used independently or in combination with each other.

The active pattern ACT of the transistor TR may be disposed on the buffer layer BFR. The active pattern ACT may include a source area, a drain area, and a channel area between the source area and the drain area. The active pattern ACT may include a silicon semiconductor material, an oxide semiconductor material, or the like. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. In some cases, these materials may be used independently or in combination with each other.

The gate insulating layer GI may be disposed on the active pattern ACT, and may cover at least a portion of the active pattern ACT. The gate insulating layer GI may include an inorganic material such as silicon oxide, silicon nitride, silicon oxynitride, or the like. In some cases, these materials may be used independently or in combination with each other.

The gate electrode GE of the transistor TR may be disposed on the gate insulating layer GI. The gate electrode GE may overlap the channel area of the active pattern ACT in a plan view. The gate electrode GE may include a metal, an alloy, a conductive metal oxide, a conductive metal nitride, a transparent conductive material, or the like. In some cases, these materials may be used independently or in combination with each other.

The interlayer insulating layer ILD may be disposed on the gate electrode GE, and may cover the gate electrode GE. In some cases, the interlayer insulating layer ILD may cover the side surfaces of the gate electrode GE of the transistor, the side surfaces of the gate insulating layer GI, the top surface and side surfaces of the active patter ACT of the transistor, and the top surface of the buffer layer BFR. In some cases, the interlayer insulating layer ILD is disposed on the buffer layer BFR. The interlayer insulating layer ILD may include an inorganic material such as silicon oxide, silicon nitride, silicon oxynitride, or the like. In some cases, these materials may be used independently or in combination with each other.

The first electrode SE of the transistor TR and the second electrode DE of the transistor TR may be disposed on the interlayer insulating layer ILD. The first electrode SE may be connected to the source area of the active pattern ACT through a first contact hole penetrating the gate insulating layer GI and the interlayer insulating layer ILD. In some cases, the second electrode DE may be connected to the drain area of the active pattern ACT through a second contact hole penetrating the gate insulating layer GI and the interlayer insulating layer ILD. Each of the first electrode SE and the second electrode DE may include a metal, an alloy, a conductive metal oxide, a conductive metal nitride, a transparent conductive material, or the like. In some cases, these materials may be used independently or in combination with each other.

Accordingly, the transistor TR including the active pattern ACT, the gate electrode GE, the first electrode SE, and the second electrode DE may be disposed on the substrate SUB. The transistor TR may be included in the pixel circuit.

The via insulating layer VIA may be disposed on the first electrode SE of the transistor TR and the second electrode DE of the transistor TR, and may cover the first electrode SE of the transistor TR and the second electrode DE of the transistor TR. In some embodiments, the via insulating layer VIA may be disposed on and cover the first electrode SE of the transistor TR, the second electrode DE of the transistor TR, and the interlayer insulating layer ILD. The via insulating layer VIA may include an organic material such as a phenol resin, an acrylic resin, a polyimide resin, a polyamide resin, a siloxane resin, an epoxy resin, or the like. In some cases, these materials may be used independently or in combination with each other.

In some embodiments, a thickness of the via insulating layer VIA might not be constant. For example, the thickness of the via insulating layer VIA may be a length measured from one surface adjacent to the substrate SUB of the via insulating layer VIA (e.g., a lower surface of the via insulating layer VIA) to the other surface spaced apart from the substrate SUB of the via insulating layer VIA (e.g., an upper surface of the via insulating layer VIA) measured in the third direction DR3.

In an embodiment, the via insulating layer VIA may have different thicknesses in a pixel electrode area PA, which overlaps the first, second, and third pixel electrodes PE1, PE2, and PE3 in a plan view, and in a non-pixel electrode area NPA, which does not overlap the first, second, and third pixel electrodes PE1, PE2, and PE3 in a plan view. The via insulating layer VIA may have a first thickness TH1 in the pixel electrode area PA (e.g., PA1, PA2, and PA3), and may have a second thickness TH2 in the non-pixel electrode area NPA (e.g., the non-pixel electrode area NPA overlapping pixel defining layer PDL1 and PDL2). In some cases, the non-pixel electrode area NPA in the region having the first distance D1 may be referred to as the first non-pixel electrode area. In some cases, the non-pixel electrode area NPA in the region having the second distance D2 may be referred to as the second non-pixel electrode area. In an embodiment, the first thickness TH1 may be greater than the second thickness TH2. The upper surface of the via insulating layer VIA might not be flat. For example, in the non-pixel electrode area NPA, the upper surface of the via insulating layer VIA may be recessed toward the lower surface of the via insulating layer VIA so that the via insulating layer VIA has the second thickness TH2. For example, the upper surface of the via insulating layer VIA in the pixel electrode area PA may further protrude in the third direction DR3 than the upper surface of the via insulating layer VIA in the non-pixel electrode area NPA. For example, the upper surface of the via insulating layer VIA in the pixel electrode area PA may be at a higher level than the upper surface of the via insulating layer VIA in the non-pixel electrode area NPA.

For example, the first thickness TH1 may be about 3 μm and the second thickness TH2 may be about 2.0 μm to about 2.5 μm. For example, the upper surface of the via insulating layer VIA in the non-pixel electrode area NPA may be recessed by about 0.5 μm to about 1.0 μm toward the lower surface of the via insulating layer VIA. For example, the upper surface of the via insulating layer VIA in the non-pixel electrode area NPA may be recessed by about 0.5 μm to about 1.0 μm from the upper surface of the via insulating layer VIA in the pixel electrode area PA. However, the present disclosure is not limited thereto.

The first, second, and third pixel electrodes PE1, PE2 and PE3 may be disposed on the via insulating layer VIA. For example, the first pixel electrode PE1, the second pixel electrode PE2, and the third pixel electrode PE3 may be disposed on the vial insulating layer VIA in the first pixel electrode area PA1, the second pixel electrode area PA2, and the third pixel electrode area PA3, respectively. Each of the first, second, and third pixel electrodes PE1, PE2 and PE3 may be electrically connected to the pixel circuit. For example, referring to FIG. 3, the first pixel electrode PE1 may be electrically connected to the transistor TR. The first pixel electrode PE1 may be connected to the second electrode DE (or the first electrode SE) of the transistor TR through a contact hole penetrating the via insulating layer VIA.

Each of the first, second, and third pixel electrodes PE1, PE2, and PE3 may have a multi-layer structure. For example, each of the first, second, and third pixel electrodes PE1, PE2, and PE3 may include a first layer disposed on the via insulating layer VIA, a second layer disposed on the first layer, and a third layer disposed on the second layer. The first, second, and third pixel electrodes PE1, PE2, and PE3 may include a metal, an alloy, a conductive metal oxide, a conductive metal nitride, a transparent conductive material, or the like. These materials may be used independently or in combination with each other. For example, each of the first layer and the third layer may include indium tin oxide (ITO), and the second layer may include silver (Ag), but the present disclosure is not limited thereto.

In some cases, boundaries of the first, second, and third pixel electrodes PE1, PE2 and PE3 may represent boundaries of the pixel electrode area PA and the non-pixel electrode area NPA. For example, the pixel electrode area PA may be an area in which the first, second, and third pixel electrodes PE1, PE2 and PE3 are disposed, and the non-pixel electrode area NPA may be an area in which the first, second, and third pixel electrodes PE1, PE2 and PE3 are not disposed.

The pixel electrode area PA may include first, second, and third pixel electrode areas PA1, PA2 and PA3. An area in which the first pixel electrode PE1 is disposed may be represented as the first pixel electrode area PA1, an area in which the second pixel electrode PE2 is disposed may be represented as the second pixel electrode area PA2, and an area in which the third pixel electrode PE3 is disposed may be represented as the third pixel electrode area PA3. An area in which the first, second, and third pixel electrodes PE1, PE2, and PE3 are spaced apart from each other may be defined as the non-pixel electrode area NPA. For example, an area spaced apart from the first and second pixel electrode areas PA1 and PA2 may represent the non-pixel electrode area NPA having a first distance D1. For example, an area spaced apart from the first and third pixel electrode areas PA1 and PA3 may represent the non-pixel electrode area NPA having a second distance D2.

The first, second, and third pixel electrodes PE1, PE2, and PE3 included in the same pixel PX may be spaced apart from each other by at least the first distance D1. For example, the first pixel electrode PE1 and the second pixel electrode PE2 included in the same pixel PX may be spaced apart from each other by the first distance D1 in the first direction DR1, and the non-pixel electrode area NPA having the first distance D1 in the first direction DR1 may be in a region between the first pixel electrode PE1 and the second pixel electrode PE2.

The first, second, and third pixel electrodes PE1, PE2, and PE3 included in different pixels PX adjacent to each other may be spaced apart from each other by the second distance D2. For example, the first pixel electrode PE1 included in a first pixel PX and the third pixel electrode PE3 included in a second pixel PX adjacent to the first pixel PX may be spaced apart from each other by the second distance D2 in the first direction DR1, and a non-pixel electrode area NPA having the second distance D2 in the first direction DR1 may be in a region between the first pixel electrode PE1 and the third pixel electrode PE3.

The pixel defining layer PDL may be disposed on the via insulating layer VIA and the first, second, and third pixel electrodes PE1, PE2 and PE3. The pixel defining layer PDL may be disposed in a portion of the pixel electrode area PA and in the non-pixel electrode area NPA. The pixel defining layer PDL may fill a portion in which the via insulating layer VIA is recessed in the non-pixel electrode area NPA, and may represent openings exposing at least a portion of each of the first, second, and third pixel electrodes PE1, PE2 and PE3 in the pixel electrode area PA. In some embodiments, the pixel defining layer PDL may cover a potion of upper surfaces of each of the first, second, and third pixel electrodes PE1, PE2 and PE3 in the pixel electrode area PA. The pixel defining layer PDL may include an organic material such as a polyimide resin, an epoxy resin, a siloxane resin, or the like. These materials may be used independently or in combination with each other.

The pixel defining layer PDL may include a first pixel defining layer PDL1 and a second pixel defining layer PDL2. In an embodiment, the first pixel defining layer PDL1 may be disposed in the non-pixel electrode area NPA having the first distance D1, and the second pixel defining layer PDL2 may be disposed in the non-pixel electrode area NPA having the second distance D2. When pixel electrodes adjacent to each other are spaced apart from each other by the first distance D1, the first pixel defining layer PDL1 may be disposed on the corresponding pixel electrodes. When pixel electrodes adjacent to each other are spaced apart from each other by the second distance D2, the second pixel defining layer PDL2 may be disposed on the corresponding pixel electrodes.

In an embodiment, the first pixel defining layer PDL1 and the second pixel defining layer PDL2 may have different cross-sectional shapes. For example, the first pixel defining layer PDL1 may include a groove H. The groove H may be between the first pixel defining layer PDL1 and pixel electrodes (e.g., the first and second pixel electrodes PEL and PE2) adjacent to the first pixel defining layer PDL1 in a cross-sectional view. The groove H may overlap the pixel electrodes (e.g., the first and second pixel electrodes PEL and PE2) adjacent to the first pixel defining layer PDL1 in a plan view. In some cases, the first pixel defining layer PDL1 may be spaced apart from the pixel electrodes (e.g., the first and second pixel electrodes PE1 and PE2) in the third direction DR3 by the groove H in the pixel electrode area PA. The first pixel defining layer PDL1 might not be in contact with an upper surface of each of the pixel electrodes (e.g., the first and second pixel electrodes PEL and PE2) adjacent to the first pixel defining layer PDL1 or may be spaced apart by a distance represented by the groove H. In some cases, the second pixel defining layer PDL2 may be in contact with at least a portion of an upper surface of each of the pixel electrodes (e.g., the first and third pixel electrodes PE1 and PE3) adjacent to the second pixel defining layer PDL2. For example, a portion of a side surface of the first pixel defining layer PDL1 may be recessed to represent the groove H. For example, in an embodiment, the first pixel defining layer PDL1 may have an undercut shape in a cross-sectional view.

For example, the first and second pixel electrodes PEL and PE2 may be spaced apart from each other by the first distance D1 in the first direction DR1. In some cases, the first pixel defining layer PDL1 may be disposed on a portion of each of the first and second pixel electrodes PE1 and PE2 and on the via insulating layer VIA between the first and second pixel electrodes PE1 and PE2. For example, the first pixel defining layer PDL1 may be disposed in the non-pixel electrode area NPA having the first distance D1 between the first and second pixel electrodes PE1 and PE2 and in at least a portion of each of the first and second pixel electrode areas PA1 and PA2. The first pixel defining layer PDL1 may include the groove H overlapping the first and second pixel electrodes PEL and PE2 in a plan view. The groove H may be between the first pixel defining layer PDL1 and each of the first and second pixel electrodes PE1 and PE2. The first pixel defining layer PDL1 may be spaced apart from the first and second pixel electrodes PE1 and PE2 in the third direction DR3 and in the first and second pixel electrode areas PA1 and PA2 by the groove H. The first pixel defining layer PDL1 might not be in contact with an upper surface of each of the first and second pixel electrodes PE1 and PE2 by the groove H. In some cases, a side surface of the first pixel electrode PE1 may be in contact with a portion of a first side surface of the first pixel defining layer PDL1, and a side surface of the second pixel electrode PE2 may be in contact with a portion of a second side surface of the first pixel defining layer PDL1 opposite from the first side surface.

In some cases, for example, the first and third pixel electrodes PEL and PE3 may be spaced apart from each other by the second distance D2 in the first direction DR1. In some cases, the second pixel defining layer PDL2 may be disposed on a portion of each of the first and third pixel electrodes PEL and PE3 and on the via insulating layer VIA between the first and third pixel electrodes PEL and PE3. For example, the second pixel defining layer PDL2 may be disposed in the non-pixel electrode area NPA having the second distance D2 between the first and third pixel electrodes PEL and PE3 and in at least a portion of each of the first and third pixel electrode areas PA1 and PA3. The second pixel defining layer PDL2 may cover at least a portion (e.g., a side portion) of each of the first and third pixel electrodes PEL and PE3 in the first and third pixel electrode areas PA1 and PA3. The second pixel defining layer PDL2 may be in contact with at least a portion of an upper surface of each of the first and third pixel electrodes PE1 and PE3. In some embodiments, a lower surface of the second pixel defining layer PDL2 and a lower surface of the first pixel defining layer PDL1 are in a same level. In some cases, an upper surface of the second pixel defining layer PDL2 and an upper surface of the first pixel defining layer PDL1 are in a same level.

In an embodiment, a sacrificial pattern SP may be at least partially disposed in the groove H. For example, a portion of the sacrificial pattern SP remaining without being removed in a manufacturing process of the display device 10 may be disposed in the groove H. In an embodiment, the sacrificial pattern SP may include a material different from that of the first, second, and third pixel electrodes PE1, PE2, and PE3. The sacrificial pattern SP may include a material having a crystallization temperature higher than that of a material included in an uppermost layer of each of the first, second, and third pixel electrodes PE1, PE2, and PE3 (e.g., the third layer of each of the first, second, and third pixel electrodes PE1, PE2, and PE3). For example, the sacrificial pattern SP may include a material having a crystallization temperature higher than a temperature at which a manufacturing process of the pixel defining layer PDL (e.g., a curing process of the pixel defining layer PDL) is performed, and the uppermost layer of each of the first, second, and third pixel electrodes PE1, PE2, and PE3 may include a material having a crystallization temperature lower than the temperature at which the manufacturing process of the pixel defining layer PDL is performed. In some cases, the sacrificial pattern SP may be disposed at a portion of the first pixel electrode area PA1 and a portion of the second pixel electrode area PA2.

In an embodiment, etching selectivities of the sacrificial pattern SP and the first, second, and third pixel electrodes PE1, PE2 and PE3 may be different. The sacrificial pattern SP may have etching selectivity higher than that of the first, second, and third pixel electrodes PE1, PE2, and PE3 with respect to an etchant that may be used when patterning the sacrificial pattern SP (e.g., when removing the sacrificial pattern SP). For example, when the sacrificial pattern SP is patterned, the uppermost layer of each of the first, second, and third pixel electrodes PE1, PE2, and PE3 may include a crystallized material, and the sacrificial pattern SP may include an uncrystallized material, and accordingly, the etching selectivity of the sacrificial pattern SP may be relatively higher than that of the first, second, and third pixel electrodes PE1, PE2, and PE3. For example, the uppermost layer of each of the first, second, and third pixel electrodes PE1, PE2, and PE3 may include indium tin oxide (ITO), and the sacrificial pattern SP may include indium zinc oxide (IZO), but the present disclosure is not limited thereto.

A length of the sacrificial pattern SP in the first direction DR1 may be less than a length of the groove H in the first direction DR1. The sacrificial pattern SP may cover at least a portion of the pixel electrodes (e.g., the first and second pixel electrodes PE1 and PE2) in the pixel electrode area PA in which the groove His located. For example, the sacrificial pattern SP may cover side portions (e.g., upper surface of an end) of the first and second pixel electrodes PE1 and PE2 in the first and second pixel electrode areas PA1 and PA2.

However, the present disclosure is not limited thereto, and in another embodiment, the sacrificial pattern SP might not be disposed in the groove H. For example, the sacrificial pattern SP may be completely removed in the manufacturing process of the display device 10.

The intermediate layer ML may be disposed on the first, second, and third pixel electrodes PE1, PE2, and PE3 and the first and second pixel defining layers PDL1 and PDL2. In some cases, the intermediate layer ML may cover upper surfaces of the first and second pixel electrodes PE1 and PE2. In some cases, the intermediate layer ML may cover the upper surface and side surfaces of the first and second pixel defining layers PDL1 and PDL2. The intermediate layer ML may have a multi-layer structure. For example, as shown in FIG. 4, the intermediate layer ML may include a first common layer CL1, a first light emitting layer EL1, a second common layer CL2, a charge generation layer CGL, a third common layer CL3, a second light emitting layer EL2, and a fourth common layer CL4. In some embodiments, these layers may be sequentially stacked.

The first common layer CL1 may have a single-layer structure or a multi-layer structure. For example, the first common layer CL1 may include at least one of a hole injection layer and a hole transport layer.

The first light emitting layer EL1 may be disposed on the first common layer CL1. The first light emitting layer EL1 may be disposed on the first, second, and third pixel electrodes PE1, PE2, and PE3 exposed by the pixel defining layer PDL. The first light emitting layer EL1 may emit light of a specific wavelength band, and may include a material that emits the light.

The second common layer CL2 may be disposed on the first common layer CL1 and the first light emitting layer EL1. In some cases, the second common layer CL2 may be directly disposed on and contacts the first light emitting layer EL1. The second common layer CL2 may have a single-layer structure or a multi-layer structure. For example, the second common layer CL2 may include an electron transport layer.

The charge generation layer CGL may be disposed on the second common layer CL2. The charge generation layer CGL may have a single-layer structure or a multi-layer structure. The charge generation layer CGL may adjust a charge balance between the first light emitting layer EL1 and the second light emitting layer EL2. For example, the charge generation layer CGL may include an n-type charge generation layer that provides electrons to the first light emitting layer EL1 and a p-type electron generation layer that provides holes to the second light emitting layer EL2.

The third common layer CL3 may be disposed on the charge generation layer CGL. The third common layer CL3 may have a single-layer structure or a multi-layer structure. For example, the third common layer CL3 may include a hole transport layer.

The second light emitting layer EL2 may be disposed on the third common layer CL3. The second light emitting layer EL2 may overlap the first light emitting layer EL1 in a plan view. For example, the second light emitting layer EL2 may be disposed on the first, second, and third pixel electrodes PE1, PE2, and PE3 exposed by the pixel defining layer PDL. The second light emitting layer EL2 may emit light of a specific wavelength band, and may include a material that emits the light.

The fourth common layer CL4 may be disposed on the third common layer CL3 and the second light emitting layer EL2. In some cases, the fourth common layer CL4 may be disposed directly on and contacts the second light emitting layer EL2. The fourth common layer CL4 may have a single-layer structure or a multi-layer structure. For example, the fourth common layer CL4 may include at least one of an electron injection layer and an electron transport layer.

In an embodiment, the intermediate layer ML may be disconnected by the first pixel defining layer PDL1. The intermediate layer ML may be disconnected by a shape (e.g., an undercut shape) of the first pixel defining layer PDL1 having the groove H. The intermediate layer ML may include a first portion disposed on the first, second, and third pixel electrodes PE1, PE2, and PE3 and the second pixel defining layer PDL2 and a second portion disposed on the first pixel defining layer PDL1. The first portion and the second portion may be spaced apart from each other. In some cases, the first portion and the second portion of the intermediate layer ML might not be in contact with each other.

For example, the intermediate layer ML may be disconnected between relatively more adjacent light emitting elements. For example, the first portion and the second portion of the intermediate layer ML may be disconnected between the light emitting elements (e.g., the first light emitting element LE1 and the second light emitting element LE2). In an embodiment, the intermediate layer ML may be disconnected between light emitting elements including pixel electrodes (e.g., the first and second pixel electrodes PE1 and PE2) spaced apart by the first distance D1. Accordingly, leakage current that may occur between the light emitting elements may be reduced, and color mixing between the light emitting elements may be reduced.

For example, the intermediate layer ML may be disconnected between the first and second light emitting elements LE1 and LE2 including the first and second pixel electrodes PE1 and PE2 spaced apart from each other by the first distance D1 in the first direction DR1. In some cases, the intermediate layer ML might not be disconnected between the first and third light emitting elements LE1 and LE3 including the first and third pixel electrodes PE1 and PE3 spaced apart from each other by the second distance D2 in the first direction DR1. For example, the intermediate layer ML may be continuous between the first and second light emitting elements LE1 and LE2. Accordingly, leakage current that may occur between the first and second light emitting elements LE1 and LE2 may be minimized to minimize color mixing between the first and second light emitting elements LE1 and LE2.

For example, the charge generation layer CGL included in the intermediate layer ML may be disconnected by the first pixel defining layer PDL1. The charge generation layer CGL may include a first portion disposed on the first, second, and third pixel electrodes PE1, PE2, and PE3 and the second pixel defining layer PDL2 and a second portion disposed on the first pixel defining layer PDL1. The first portion and the second portion may be spaced apart from each other. When the charge generation layer CGL is extended without being disconnected between the first, second, and third light emitting elements LE1, LE2, and LE3, leakage current (i.e., side leakage current) may occur between relatively more adjacent light emitting elements (e.g., light emitting elements including pixel electrodes spaced apart from each other by the first distance D1). Accordingly, since the charge generation layer CGL is disconnected by the first pixel defining layer PDL1, leakage current that may occur between the light emitting elements adjacent to each other may be minimized.

Although FIG. 4 illustrates that the intermediate layer ML includes a structure in which two light emitting layers and one charge generation layer are stacked, the present disclosure is not limited thereto. For example, the intermediate layer ML may have a structure in which one or more light emitting layers or two or more charge generation layers are stacked.

The common electrode CE may be disposed on the intermediate layer ML. The common electrode CE may extend continuously in the display area DA. In some cases, the common electrode CE of the light emitting elements may cover the intermediate layer ML and a portion of the first pixel defining layer PDL1. In some cases, a lower surface of the common electrode CE may be in contact with the first pixel defining layer PDL1. In some cases, a portion of the common electrode CE may be disposed in the disconnection between the first portion and the second portion of the intermediate layer ML. The common electrode CE may include a metal, an alloy, a conductive metal oxide, a conductive metal nitride, a transparent conductive material, or the like. These materials may be used independently or in combination with each other.

Accordingly, the first light emitting element LE1 including the first pixel electrode PE1, the intermediate layer ML, and the common electrode CE may be disposed in the first pixel electrode area PA1 on the substrate SUB. The second light emitting element LE2 including the second pixel electrode PE2, the intermediate layer ML, and the common electrode CE may be disposed in the second pixel electrode area PA2 on the substrate SUB. The third light emitting element LE3 including the third pixel electrode PE3, the intermediate layer ML, and the common electrode CE may be disposed in the third pixel electrode area PA3 on the substrate SUB.

The encapsulation layer TFE may be disposed on and covers an upper surface of the common electrode CE. The encapsulation layer TFE may prevent impurities, moisture, outside air, or the like from penetrating into the first, second, and third light emitting elements LE1, LE2, and LE3 from the outside. The encapsulation layer TFE may include at least one inorganic encapsulation layer and at least one organic encapsulation layer.

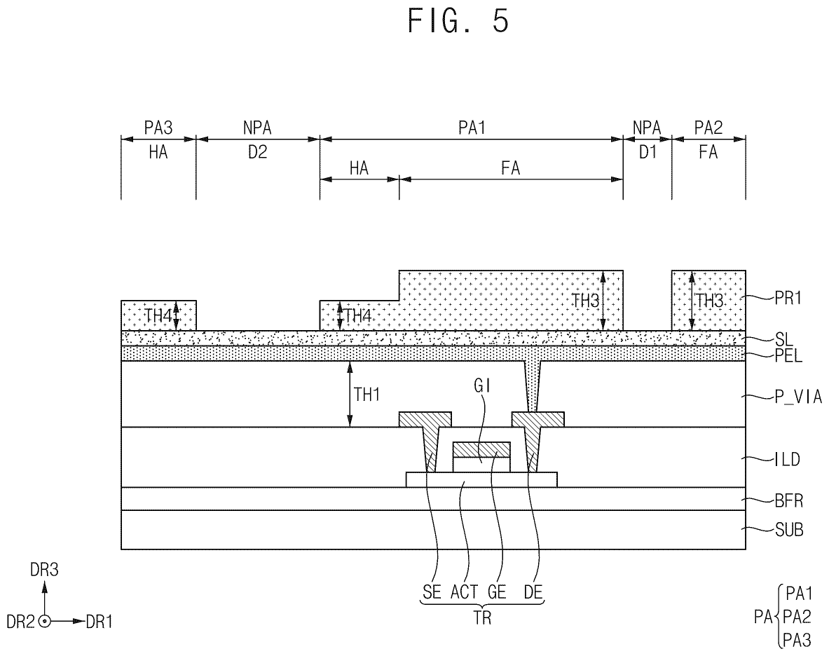

FIGS. 5, 6, 7, 8, 9, 10, 11, and 12 are views illustrating a method for manufacturing a display device according to an embodiment of the present disclosure. A method of manufacturing a display device described with reference to FIGS. 5, 6, 7, 8, 9, 10, 11, and 12 may be a method of manufacturing the display device 10 described with reference to FIGS. 1, 2, 3, and 4. Hereinafter, redundant descriptions may be omitted or simplified.

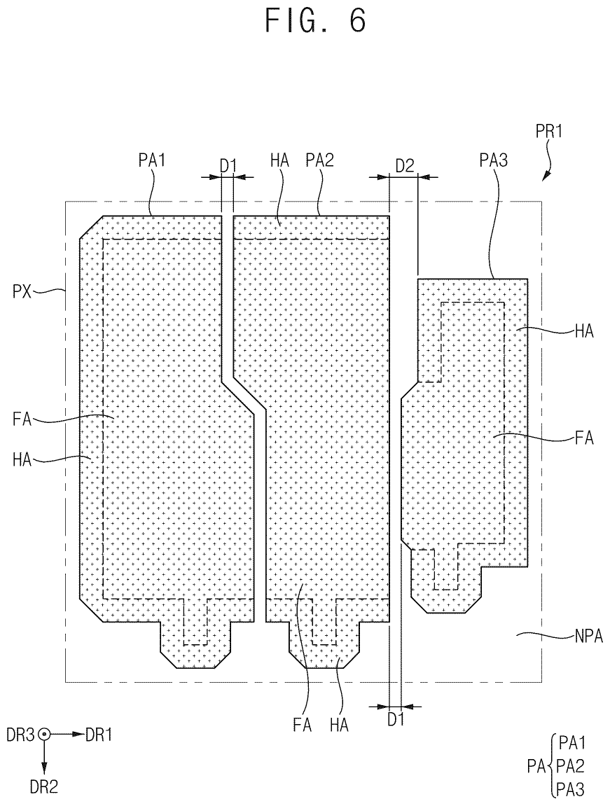

Referring to FIGS. 5 and 6, the buffer layer BFR, the active pattern ACT, the gate insulating layer GI, the gate electrode GE, the interlayer insulating layer ILD, the first and second electrodes SE and DE, a preliminary via insulating layer P_VIA, a pixel electrode layer PEL, a sacrificial layer SL, and a first photoresist pattern PR1 may be sequentially formed on the substrate SUB. In some embodiments, the active pattern ACT may be disposed on the buffer layer BFR to cover a portion of the buffer layer BFR. In some embodiments, contact holes may be formed through the interlayer insulating layer ILD, where the first and second electrodes SE and DE are placed in the contact holes.

The preliminary via insulating layer P_VIA may cover the first and second electrodes SE and DE, and may include an organic material such as a phenol resin, an acrylic resin, a polyimide resin, a polyamide resin, a siloxane resin, an epoxy resin, or the like. The preliminary via insulating layer P_VIA may have a first thickness TH1. For example, the first thickness TH1 of the preliminary via insulating layer P_VIA may be a length measured from one surface adjacent to the substrate SUB of the preliminary via insulating layer P_VIA (e.g., a lower surface of the preliminary via insulating layer P_VIA) to the other surface spaced apart from the substrate SUB of the preliminary via insulating layer P_VIA (e.g., an upper surface of the preliminary via insulating layer P_VIA) in the third direction DR3.

The pixel electrode layer PEL may be formed on the preliminary via insulating layer P_VIA. The pixel electrode layer PEL may be electrically connected to the pixel circuit (e.g., the transistor TR). For example, a contact hole may be formed through the preliminary via insulating layer P_VIA, where the pixel electrode layer PEL extends into the contact hole and contacts the upper surface of the second electrode DE (or the first electrode SE) of the transistor TR. The pixel electrode layer PEL may have a multi-layer structure. For example, the pixel electrode layer PEL may include a first layer disposed on the preliminary via insulating layer P_VIA, a second layer disposed on the first layer, and a third layer disposed on the second layer. The pixel electrode layer PEL may include a metal, an alloy, a conductive metal oxide, a conductive metal nitride, a transparent conductive material, or the like. For example, each of the first layer and the third layer may include indium tin oxide, and the second layer may include silver, but the present disclosure is not limited thereto.

The sacrificial layer SL may be formed on the pixel electrode layer PEL. In an embodiment, the sacrificial layer SL may include a material different from that of the pixel electrode layer PEL. The sacrificial layer SL may include a material having a higher crystallization temperature than that of a material included in an uppermost layer of the pixel electrode layer PEL (e.g., the third layer of the pixel electrode layer PEL). For example, the uppermost layer of the pixel electrode layer PEL may include a material having a crystallization temperature lower than a temperature at which a manufacturing process of the pixel defining layer PDL is performed, and the sacrificial layer SL may include a material having a crystallization temperature higher than the temperature at which the manufacturing process of the pixel defining layer PDL is performed. For example, the uppermost layer of the pixel electrode layer PEL may include indium tin oxide, and the sacrificial layer SL may include indium zinc oxide, but the present disclosure is not limited thereto.

The first photoresist pattern PR1 may be formed on the sacrificial layer SL. In an embodiment, the first photoresist pattern PR1 may be formed using a half-tone mask. For example, a photoresist layer including a photosensitive material may be formed on the sacrificial layer SL, and the photoresist layer may be patterned using a half-tone mask to form the first photoresist pattern PR1.

The first photoresist pattern PR1 may be formed in the pixel electrode area PA (e.g., PA1, PA2, and PA3), and might not be formed in the non-pixel electrode area NPA. In some cases, the first photoresist pattern PR1 may include a full-tone area FA and a half-tone area HA in the pixel electrode area PA. The first photoresist pattern PR1 may have different thicknesses in the full-tone area FA and the half-tone area HA. For example, the thickness of the first photoresist pattern PR1 may be a length measured from one surface adjacent to the substrate SUB of the first photoresist pattern PR1 (e.g., a lower surface of the first photoresist pattern PR1) to the other surface spaced apart from the substrate SUB of the first photoresist pattern PR1 (e.g., an upper surface of the first photoresist pattern PR1) in the third direction DR3. The first photoresist pattern PR1 may have a third thickness TH3 in the full-tone area FA, and may have a fourth thickness TH4 in the half-tone area HA. The third thickness TH3 may be greater than the fourth thickness TH4.

In an embodiment, the full-tone area FA may be adjacent to the non-pixel electrode area NPA having the first distance D1, and the half-tone area HA may be adjacent to the non-pixel electrode area NPA having the second distance D2. For example, in the first, second, and third pixel electrode areas PA1, PA2, and PA3 adjacent to each other, an area in which the first, second, and third pixel electrode areas PA1, PA2, and PA3 are spaced apart by a relatively small distance (i.e., an area spaced apart by the first distance D1) may be the full-tone area FA, and an area in which the first, second, and third pixel electrode areas PA1, PA2, and PA3 are spaced apart by a relatively large distance (i.e., an area spaced apart by the second distance D2) may be the half-tone area HA. For example, an edge of an area spaced apart from each other by the second distance D2 among the first, second, and third pixel electrode areas PA1, PA2, and PA3 adjacent to each other may be the half-tone area HA, and a remaining area among the first, second, and third pixel electrode areas PA1, PA2, and PA3 may be the full-tone area FA (see also FIGS. 2 and 6).

For example, the first photoresist pattern PR1 may have the fourth thickness TH4 at an edge of an area spaced apart from each other by the second distance D2 among the first, second, and third pixel electrode areas PA1, PA2, and PA3 adjacent to each other. In some cases, the first photoresist pattern PR1 may have the third thickness TH3 in a remaining area among the first, second, and third pixel electrode areas PA1, PA2, and PA3 adjacent to each other. For example, the first photoresist pattern PR1 may have the fourth thickness TH4 in an area adjacent to the non-pixel electrode area NPA of the second distance D2 among the first, second, and third pixel electrode areas PA1, PA2, and PA3, and may have the third thickness TH3 in a remaining area among the first, second, and third pixel electrode areas PA1, PA2, and PA3.

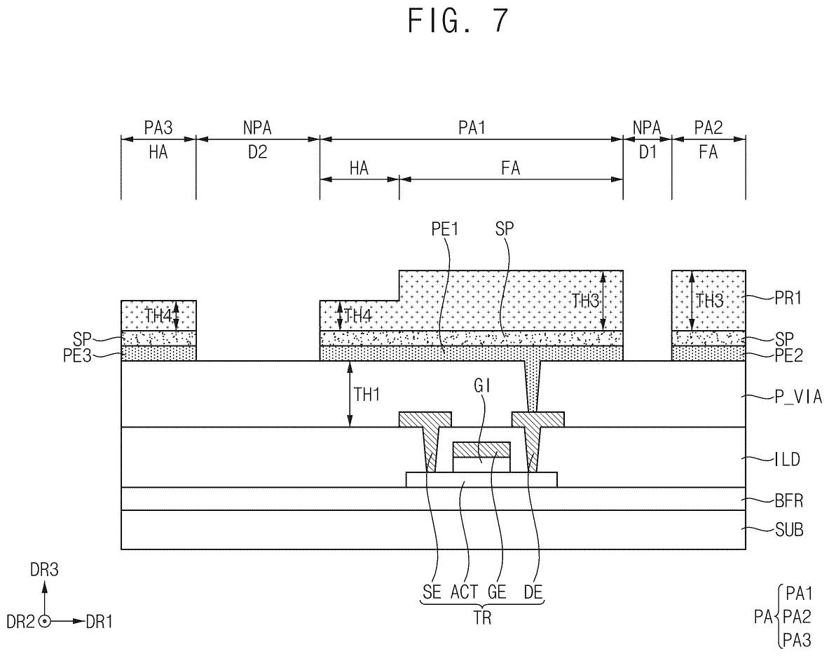

Referring to FIGS. 5 and 7, the sacrificial layer SL may be patterned using the first photoresist pattern PR1 as guidance to form a sacrificial pattern SP, and the pixel electrode layer PEL may be patterned to form the first, second, and third pixel electrodes PE1, PE2, and PE3. For example, portions of the sacrificial layer SL and the pixel electrode layer PEL are removed to expose portions of the upper surface of the preliminary via insulating layer P_VIA. In some cases, the width of the removed portion has the same width as the first photoresist pattern PR1 (e.g., the first distance D1 and the second distance D2).

Specifically, the sacrificial layer SL in the non-pixel electrode area NPA may be removed to form the sacrificial pattern SP in the pixel electrode area PA, and the pixel electrode layer PEL in the non-pixel electrode area NPA may be removed to form the first, second, and third pixel electrodes PE1, PE2, and PE3 in the first, second, and third pixel electrode areas PA1, PA2, and PA3, respectively. For example, the sacrificial pattern SP and the first, second, and third pixel electrodes PE1, PE2, and PE3 may be formed through wet etching. Accordingly, the preliminary via insulating layer P_VIA may be exposed in the non-pixel electrode area NPA.

Referring to FIGS. 7, 8, and 9, a portion of the first photoresist pattern PR1 may be removed to form a second photoresist pattern PR2, and a portion of the preliminary via insulating layer P_VIA may be removed to form the via insulating layer VIA.

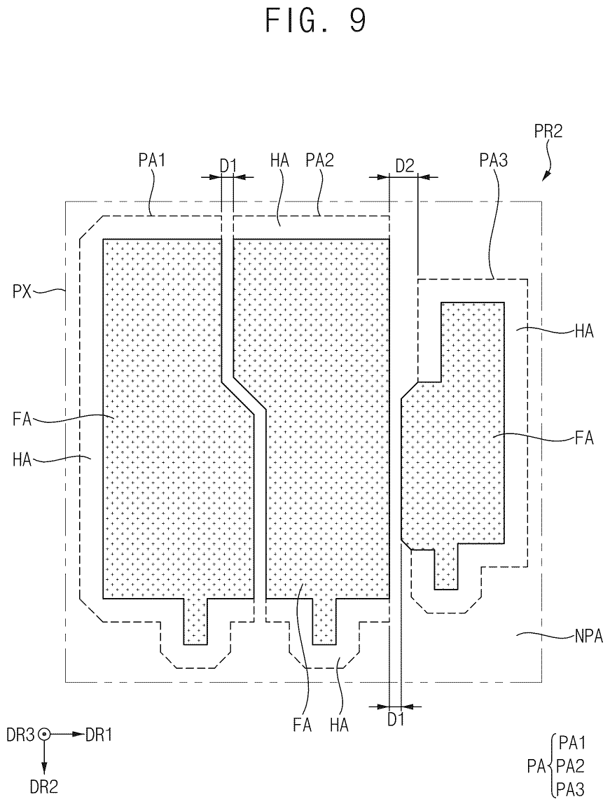

In an embodiment, the second photoresist pattern PR2 may be formed by removing the first photoresist pattern PR1 by at least a thickness of the first photoresist pattern PR1 in the half-tone area HA. For example, the first photoresist pattern PR1 may be removed by the fourth thickness TH4 in the pixel electrode area PA. The first photoresist pattern PR1 in the half-tone area HA and a portion of the first photoresist pattern PR1 in the full-tone area FA may be removed to form the second photoresist pattern PR2 in the full-tone area FA (see also FIG. 9 illustrating the removed portions in a plan view). Accordingly, the upper surface of the sacrificial pattern SP may be exposed in the half-tone area HA.

The second photoresist pattern PR2 may have a fifth thickness TH5 in the full-tone area FA. For example, the fifth thickness TH5 of the second photoresist pattern PR2 may be a length measured from one surface adjacent to the substrate SUB of the second photoresist pattern PR2 (e.g., a lower surface of the second photoresist pattern PR2) to the other surface spaced apart from the substrate SUB of the second photoresist pattern PR2 (e.g., an upper surface of the second photoresist pattern PR2) in the third direction DR3. The fifth thickness TH5 may be less than the third thickness TH3. For example, the fifth thickness TH5 may be a value obtained by subtracting the fourth thickness TH4 from the third thickness TH3.

The via insulating layer VIA may be formed by removing a portion of the preliminary via insulating layer P_VIA exposed in the non-pixel electrode area NPA. For example, the upper surface of the preliminary via insulating layer P_VIA in the non-pixel electrode area NPA may be recessed in a direction opposite to the third direction DR3 to form the via insulating layer VIA. For example, the upper surface of the preliminary via insulating layer P_VIA in the non-pixel electrode area NPA may be recessed in a direction towards the substrate SUB. In some cases, the via insulating layer VIA has the first thickness TH1 in the pixel electrode area PA and the second thickness TH2 in the non-pixel electrode area NPA.

In an embodiment, the second photoresist pattern PR2 and the via insulating layer VIA may be formed through the same process. For example, while the portion of the first photoresist pattern PR1 is removed, the portion of the preliminary via insulating layer P_VIA may be removed. For example, an ashing process of removing the portion of the first photoresist pattern PR1 and the portion of the preliminary via insulating layer P_VIA using oxygen (O₂) may be performed to form the second photoresist pattern PR2 and the via insulating layer VIA.

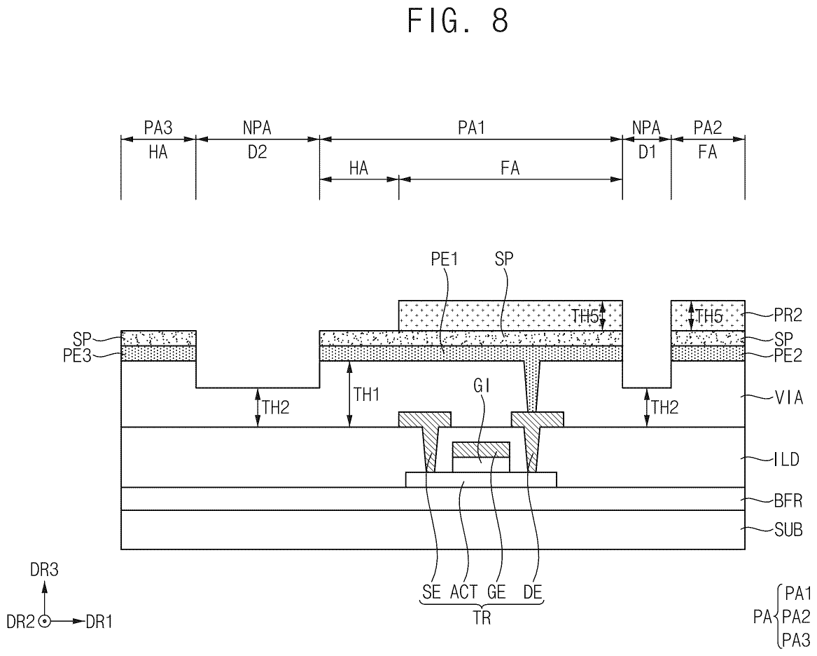

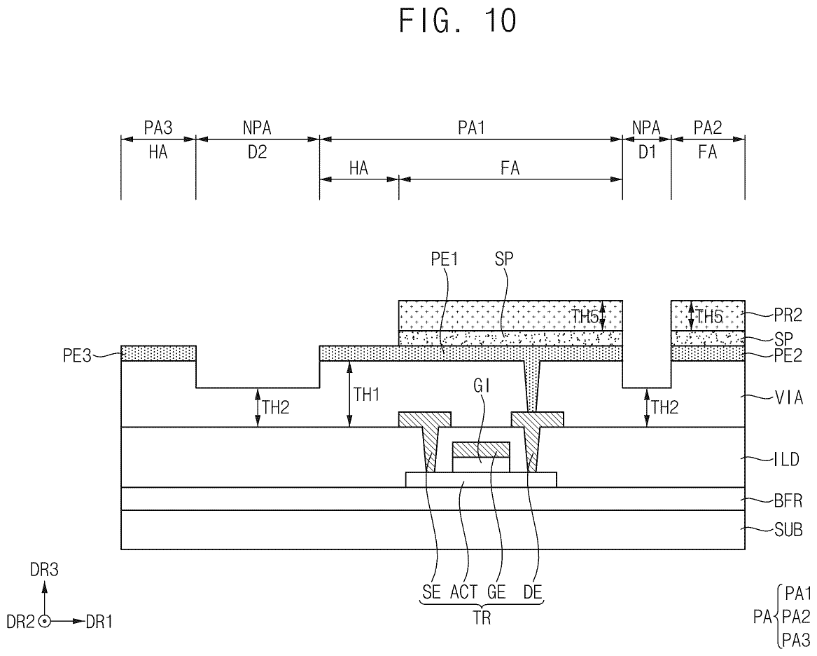

Referring to FIGS. 8 and 10, the sacrificial pattern SP may be patterned by using the second photoresist pattern PR2. The sacrificial pattern SP exposed in the half-tone area HA may be removed, so that the sacrificial pattern SP may be formed (i.e., remained) in the full-tone area FA. In some cases, sacrificial pattern SP exposed in the half-tone area HA may be removed to expose upper surface of a portion of the first pixel electrode PE1 and the third pixel electrode PE3. For example, the sacrificial pattern SP in the half-tone area HA may be removed through wet etching. Accordingly, the first, second, and third pixel electrodes PE1, PE2, and PE3 may be exposed in the half-tone area HA. For example, the first, second, and third pixel electrodes PE1, PE2, and PE3 may be exposed in an area adjacent to the non-pixel electrode area NPA of the second distance D2.

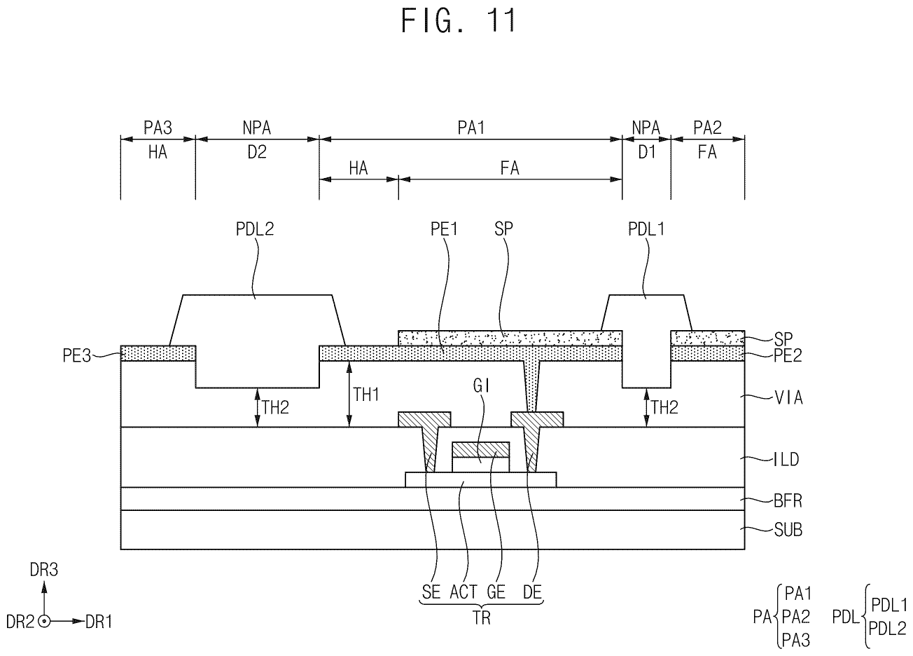

Referring to FIGS. 10 and 11, the second photoresist pattern PR2 may be removed to expose the sacrificial pattern SP in the full-tone area FA, and the pixel defining layer PDL may be formed on the via insulating layer VIA, the first, second, and third pixel electrodes PE1, PE2, and PE3, and the sacrificial pattern SP.

The pixel defining layer PDL may include the first pixel defining layer PDL1 and the second pixel defining layer PDL2. The first pixel defining layer PDL1 may be formed on the sacrificial pattern SP and on the via insulating layer VIA in the non-pixel electrode area NPA having the first distance D1. For example, the second pixel defining layer PDL2 may be formed on the via insulating layer VIA in the non-pixel electrode area NPA having the second distance D2. The first pixel defining layer PDL1 may be formed in a portion of the full-tone area FA and in the non-pixel electrode area NPA having the first distance D1, and the second pixel defining layer PDL2 may be formed in a portion of the half-tone area HA and in the non-pixel electrode area NPA having the second distance D2. For example, the first pixel defining layer PDL1 may be in contact with an upper surface of the sacrificial pattern SP disposed in the full-tone area FA, and the second pixel defining layer PDL2 may be in contact with an upper surface of each of the first, second, and third pixel electrodes PE1, PE2, and PE3 disposed in the half-tone area HA. A side surface of the first pixel defining layer PDL1 may cover the sacrificial pattern SP in the full tone area FA, and a side surface of the second pixel defining layer PDL2 may cover side surfaces of the first, second, and third pixel electrodes PE1, PE2, and PE3 in the half tone area HA.

In some embodiments, the first pixel defining layer PDL1 is disposed on the sacrificial pattern SP in the full tone area FA. In some cases, the first pixel defining layer PDL1 is disposed on the via insulating layer VIA in the non-pixel electrode area NPA having the first distance D1. For example, a portion of the side surfaces of the first pixel defining layer PDL1 may cover and contact side surfaces of the first and second pixel electrodes PEL and PE2. In some embodiments, the second pixel defining layer PDL2 is disposed on the third pixel electrodes PE3 in the half tone area HA. In some cases, the second pixel defining layer PDL2 is disposed on the via insulating layer VIA in the non-pixel electrode area NPA having the second distance D2. For example, a portion of the side surfaces of the second pixel defining layer PDL2 may cover and contact side surfaces of the first and third pixel electrodes PE1 and PE3.

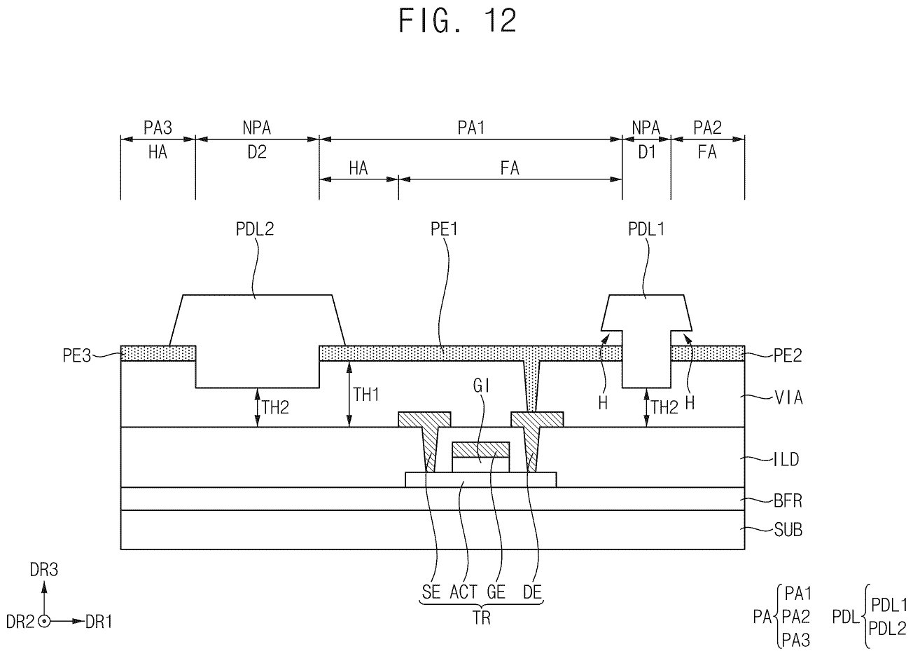

Referring to FIGS. 11 and 12, the sacrificial pattern SP may be removed to form the groove H. For example, the sacrificial pattern SP may be removed through wet etching. In this case, etching selectivity of the sacrificial pattern SP may be higher than etching selectivity of the first, second, and third pixel electrodes PE1, PE2, and PE3 with respect to an etchant that may be used when removing the sacrificial pattern SP. For example, while the pixel defining layer PDL is formed, a material included in an uppermost layer of each of the first, second, and third pixel electrodes PE1, PE2, and PE3 may be crystallized, and a material included in the sacrificial pattern SP might not be crystallized. Accordingly, the sacrificial pattern SP may be more easily removed than the first, second, and third pixel electrodes PE1, PE2, and PE3.

The groove H may be formed by removing the sacrificial pattern SP in an area in which the first pixel defining layer PDL1 and the sacrificial pattern SP overlap in a plan view. The groove H may be formed between the first pixel defining layer PDL1 and pixel electrodes adjacent to the first pixel defining layer PDL1. The groove H having a shape in which a portion of the side surface of the first pixel defining layer PDL1 is recessed may be formed, and the first pixel defining layer PDL1 may have an undercut shape in a cross-sectional view. For example, as the sacrificial pattern SP covered by the side surface of the first pixel defining layer PDL1 is removed in the full-tone area FA, the first pixel defining layer PDL1 may be spaced apart from the upper surface of each of the first, second, and third pixel electrodes PE1, PE2, and PE3 in the third direction DR3.

Although FIG. 12 illustrates that the sacrificial pattern SP is completely removed, the present disclosure is not limited thereto. In another embodiment, as illustrated in FIG. 3, the sacrificial pattern SP might not be completely removed, and a portion of the sacrificial pattern SP may remain in the groove H.

Referring back to FIG. 3, the intermediate layer ML may be formed on the first, second, and third pixel electrodes PE1, PE2, and PE3 and the pixel defining layer PDL. In an embodiment, the intermediate layer ML may be disconnected by a shape (i.e., an undercut shape) of the first pixel defining layer PDL1. The common electrode CE and the encapsulation layer TFE may be sequentially formed on the intermediate layer ML, and accordingly, the display device 10 illustrated in FIG. 3 may be manufactured. For example, the common electrode CE may be formed on the intermediate layer ML and covers the upper surface of the intermediate layer ML, the groove H, and a portion of the side surface of the first pixel defining layer PDL1. As a result, the intermediate layer ML may be disconnected by the common electrode CE. Accordingly, leakage current that may occur between the first, second, and third light emitting elements LE1, LE2, and LE3 adjacent to each other may be minimized, and thus color mixing between the first, second, and third light emitting elements LE1, LE2, and LE3 may be minimized. In some cases, the encapsulation layer TFE is formed on and covers the common electrode CE.

The display device 10 according to an embodiment of the present disclosure may include the first pixel defining layer PDL1 disposed on pixel electrodes spaced apart from each other by the first distance D1 among the first, second, and third pixel electrodes PE1, PE2, and PE3 adjacent to each other, and the second pixel defining layer PDL2 disposed on pixel electrodes spaced apart from each other by the second distance D2 among the first, second, and third pixel electrodes PE1, PE2, and PE3 adjacent to each other. The first pixel defining layer PDL1 may include the groove H, and the intermediate layer ML may be disconnected by the shape of the first pixel defining layer PDL1. Accordingly, leakage current that may occur between the first, second, and third light emitting elements LE1, LE2, and LE3 adjacent to each other may be minimized, and thus color mixing between the first, second, and third light emitting elements LE1, LE2, and LE3 may be minimized. In some cases, the shape of the first pixel defining layer PDL1 may be formed through the first photoresist pattern PR1 for patterning the first, second, and third pixel electrodes PE1, PE2, and PE3 formed using a half-tone mask, and thus a process using a separate mask for forming a structure that disconnects the intermediate layer ML might not be required.

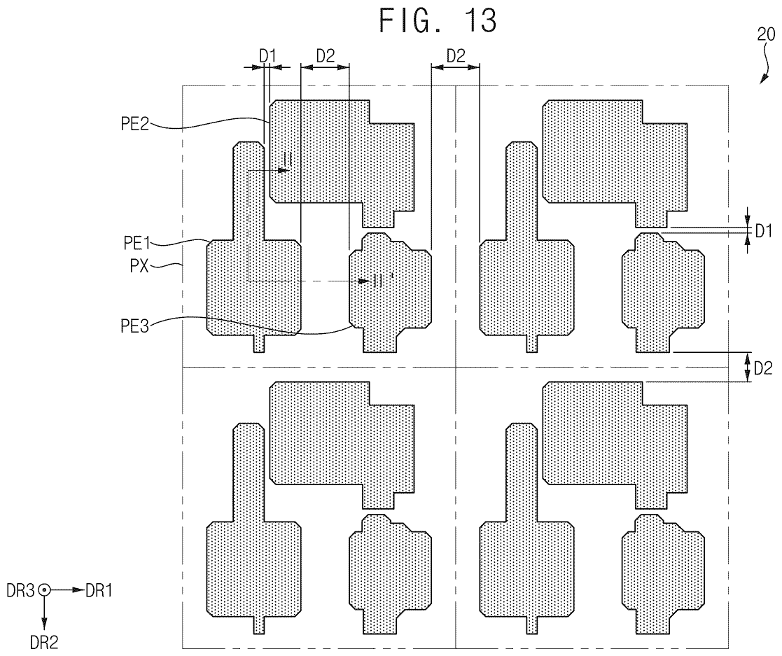

FIG. 13 an example of is a plan view schematically illustrating a portion of a display area of a display device according to an embodiment of the present disclosure. A display device 20 described with reference to FIG. 13 may be substantially the same as or similar to the display device 10 described with reference to FIGS. 1, 2, 3, and 4 except for shape and arrangement of the first, second, and third pixel electrodes PE1, PE2, and PE3. For example, FIG. 13 may correspond to the plan view of FIG. 2.

Hereinafter, descriptions of the display device 20 overlapping the display device 10 described with reference to FIGS. 1, 2, 3, and 4 may be omitted or simplified. Referring to FIG. 13, the display device 20 may include pixels PX disposed along a first direction DR1 and a second direction DR2. Each of the pixels PX may include a first pixel electrode PE1, a second pixel electrode PE2, and a third pixel electrode PE3.

In each of the pixels PX, the first, second, and third pixel electrodes PE1, PE2, and PE3 may be adjacent to each other. For example, in each of the pixels PX, the second pixel electrode PE2 may be adjacent to the first pixel electrode PE1 in a direction between the first direction DR1 and a direction opposite to the second direction DR2, and the third pixel electrode PE3 may be adjacent to the first pixel electrode PE1 in the first direction DR1 and may be adjacent to the second pixel electrode PE2 in the second direction DR2. However, the present disclosure is not limited thereto, and the arrangement of the first, second, and third pixel electrodes PE1, PE2, and PE3 may be variously changed.

In each of the pixels PX, the first, second, and third pixel electrodes PE1, PE2, and PE3 may be spaced apart from each other by a first distance D1 or a second distance D2 in a plan view. In an embodiment, the second distance D2 may be greater than or equal to the first distance D1. For example, in each of the pixels PX, the first, second, and third pixel electrodes PE1, PE2, and PE3 may be spaced apart from each other by at least the first distance D1.

In each of the pixels PX, the first pixel electrode PE1 and the second pixel electrode PE2 may be spaced apart from each other by at least the first distance D1. For example, in each of the pixels PX, a portion of the first pixel electrode PE1 and a portion of the second pixel electrode PE2 may be spaced apart by the first distance D1 in the first direction DR1, and another portion of the first pixel electrode PE1 and another portion of the second pixel electrode PE2 may be spaced apart by the second distance D2.

In some cases, in each of the pixels PX, the first pixel electrode PE1 and the third pixel electrode PE3 may be spaced apart from each other by at least the first distance D1. For example, in each of the pixels PX, the first pixel electrode PE1 and the third pixel electrode PE3 may be spaced apart by the second distance D2 in the first direction DR1.

In some cases, in each of the pixels PX, the second pixel electrode PE2 and the third pixel electrode PE3 may be spaced apart from each other by at least the first distance D1 in the second direction DR2. For example, in each of the pixels PX, a portion of the second pixel electrode PE2 and a portion of the third pixel electrode PE3 may be spaced apart by the first distance D1 in the second direction DR2, and another portion of the second pixel electrode PE2 and another portion of the third pixel electrode PE3 may be spaced apart by the second distance D2.

Pixel electrodes, which are included in different adjacent pixels PX and are most adjacent to each other, may be spaced apart from each other by the second distance D2 in a plan view. For example, in the pixels PX adjacent to each other in the first direction DR1, the third pixel electrode PE3 of a first pixel PX and the first pixel electrode PE1 of a second pixel PX adjacent to the first pixel PX in the first direction DR1 may be spaced apart by the second distance D2 in the first direction DR1. For example, in the pixels PX adjacent to each other in the second direction DR2, the first, second, and third pixel electrodes PE1, PE2, and PE3 of the first pixel PX and the first, second, and third pixel electrodes PE1, PE2, and PE3 of the second pixel PX adjacent to the first pixel PX in the second direction DR2 may be spaced apart by the second distance D2 in the second direction DR2, respectively. For example, the first and third pixel electrodes PE1 and PE3 of the first pixel PX adjacent to the second pixel electrode PE2 of the second pixel PX in the second direction DR2 may be spaced apart by the second distance D2 in the second direction DR2.

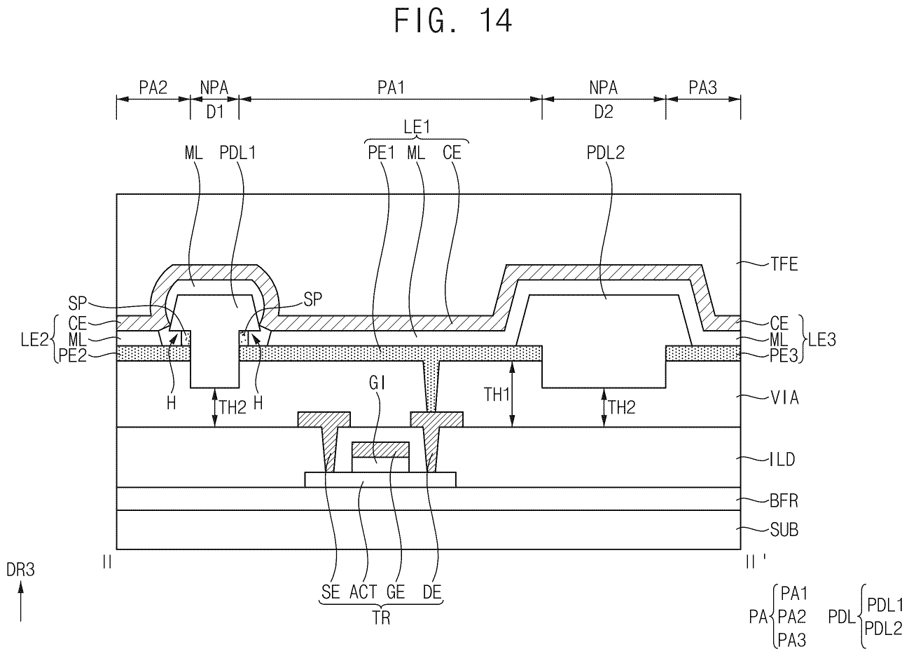

FIG. 14 is an example of a cross-sectional view taken along line II-II′ of FIG. 13. Referring to FIGS. 13 and 14, the display device 20 may include a substrate SUB, a buffer layer BFR, a transistor TR, a gate insulating layer GI, an interlayer insulating layer ILD, a via insulating layer VIA, a first light emitting element LE1, a second light emitting element LE2, a third light emitting element LE3, a pixel defining layer PDL, and an encapsulation layer TFE. In some cases, the transistor TR of the display device 20 may be substantially the same as the transistor TR of the display device 10. In some cases, the first light emitting element LE1, second light emitting element LE2, and third light emitting element LE3 of the display device 20 may be substantially the same as first light emitting element LE1, second light emitting element LE2, and third light emitting element LE3 of the display device 10.

The transistor TR may include an active pattern ACT, a gate electrode GE, a first electrode SE, and a second electrode DE. The first light emitting element LE1 may include a first pixel electrode PE1, an intermediate layer ML, and a common electrode CE, the second light emitting element LE2 may include a second pixel electrode PE2, the intermediate layer ML, and the common electrode CE, and the third light emitting element LE3 may include a third pixel electrode PE3, the intermediate layer ML, and the common electrode CE.

The buffer layer BFR, the active pattern ACT, the gate insulating layer GI, the gate electrode GE, the interlayer insulating layer ILD, and the first and second electrodes SE and DE may be sequentially disposed on the substrate SUB.

The via insulating layer VIA may be disposed on the first and second electrodes SE and DE, and may cover the first and second electrodes SE and DE of the transistor TR. A thickness of the via insulating layer VIA in the third direction DR3 might not be constant. The via insulating layer VIA may have a first thickness TH1 in a pixel electrode area PA, which overlaps the first, second, and third pixel electrodes PE1, PE2, and PE3 in a plan view. For example, the via insulating layer VIA may have a second thickness TH2 in a non-pixel electrode area NPA, which does not overlap the first, second, and third pixel electrodes PE1, PE2, and PE3 in a plan view. In an embodiment, the first thickness TH1 may be greater than the second thickness TH2. For example, an upper surface of the via insulating layer VIA may be recessed toward a lower surface of the via insulating layer VIA so that the via insulating layer VIA has the second thickness TH2 in the non-pixel electrode area NPA.

For example, the first thickness TH1 may be about 3 μm, the second thickness TH2 may be about 2.0 μm to about 2.5 μm, and the upper surface of the via insulating layer VIA may be recessed by about 0.5 μm to about 1.0 μm toward the lower surface of the via insulating layer VIA in the non-pixel electrode area NPA, but the present disclosure is not limited thereto.

The first, second, and third pixel electrodes PE1, PE2, and PE3 may be disposed on the region of the via insulating layer VIA having the first thickness TH1, and may represent the boundaries of the pixel electrode area PA and the non-pixel electrode area NPA. The pixel electrode area PA may include a first pixel electrode area PA1 with an area in which the first pixel electrode PE1 is disposed, a second pixel electrode area PA2 with an area in which the second pixel electrode PE2 is disposed, and a third pixel electrode area PA3 with an area in which the third pixel electrode PE3 is disposed. The non-pixel electrode area NPA may be an area in which the first, second, and third pixel electrodes PE1, PE2, and PE3 are not disposed.

The first, second, and third pixel electrodes PE1, PE2, and PE3 included in the same pixel PX may be spaced apart from each other by at least the first distance D1. For example, the first pixel electrode PE1 and the second pixel electrode PE2 of the same pixel PX may be spaced apart from each other by the first distance D1 in the first direction DR1, and the non-pixel electrode area NPA having the first distance D1 in the first direction DR1 may be between the first pixel electrode PE1 and the second pixel electrode PE2. For example, the first pixel electrode PE1 and the third pixel electrode PE3 of the same pixel PX may be spaced apart from each other by the second distance D2 in the first direction DR1, and the non-pixel electrode area NPA having the second distance D2 in the first direction DR1 may be between the first pixel electrode PE1 and the third pixel electrode PE3.

Each of the first, second, and third pixel electrodes PE1, PE2, and PE3 may have a multi-layer structure. For example, each of the first, second, and third pixel electrodes PE1, PE2, and PE3 may include a first layer disposed on the via insulating layer VIA, a second layer disposed on the first layer, and a third layer disposed on the second layer.

The pixel defining layer PDL may be disposed on the via insulating layer VIA and the first, second, and third pixel electrodes PE1, PE2 and PE3. The pixel defining layer PDL may be disposed in a portion of the pixel electrode area PA and in the non-pixel electrode area NPA.

The pixel defining layer PDL may include a first pixel defining layer PDL1 and a second pixel defining layer PDL2. In an embodiment, the first pixel defining layer PDL1 may be disposed in the non-pixel electrode area NPA having the first distance D1, and the second pixel defining layer PDL2 may be disposed in the non-pixel electrode area NPA having the second distance D2. When pixel electrodes adjacent to each other are spaced apart from each other by the first distance D1, the first pixel defining layer PDL1 may be disposed on the pixel electrodes, and when pixel electrodes adjacent to each other are spaced apart from each other by the second distance D2, the second pixel defining layer PDL2 may be disposed on the pixel electrodes.

In an embodiment, the first pixel defining layer PDL1 and the second pixel defining layer PDL2 may have different cross-sectional shapes. For example, the first pixel defining layer PDL1 may include a groove H between the first pixel defining layer PDL1 and pixel electrodes (e.g., the first pixel electrode PE1 and the second pixel electrode PE2) adjacent to the first pixel defining layer PDL1 in a cross-sectional view. For example, a portion of a side surface of the first pixel defining layer PDL1 may be recessed to form the groove H. Accordingly, the first pixel defining layer PDL1 might not be in contact with an upper surface of each of the pixel electrodes (e.g., the first pixel electrode PE1 and the second pixel electrode PE2) adjacent to the first pixel defining layer PDL1, and the second pixel defining layer PDL2 may be in contact with at least a portion of an upper surface of each of the pixel electrodes (e.g., the first pixel electrode PE1 and the third pixel electrode PE3) adjacent to the second pixel defining layer PDL2. For example, in an embodiment, the first pixel defining layer PDL1 may have an undercut shape in a cross-sectional view.

For example, the first and second pixel electrodes PE1 and PE2 may be spaced apart from each other by the first distance D1, and the first pixel defining layer PDL1 may be disposed on a portion of the first and second pixel electrodes PEL and PE2 and on the via insulating layer VIA between the first and second pixel electrodes PE1 and PE2. The first pixel defining layer PDL1 may include the groove H overlapping a portion of the first and second pixel electrodes PEL and PE2 in a plan view. The groove H may be between the first pixel defining layer PDL1 and each of the first and second pixel electrodes PE1 and PE2, and the first pixel defining layer PDL1 may be spaced apart from the first and second pixel electrodes PE1 and PE2 in the third direction DR3 by a distance of the groove H.

In some cases, for example, the first and third pixel electrodes PEL and PE3 may be spaced apart from each other by the second distance D2, and the second pixel defining layer PDL2 may be disposed on and contacts a portion of the first and third pixel electrodes PE1 and PE3 and on the via insulating layer VIA between the first and third pixel electrodes PEL and PE3. The second pixel defining layer PDL2 may cover at least a portion (e.g., a side portion and a side surface) of the first and third pixel electrodes PEL and PE3 in the first and third pixel electrode areas PA1 and PA3.

In an embodiment, a sacrificial pattern SP may be at least partially disposed in the groove H. For example, a portion of the sacrificial pattern SP remaining without being removed in a manufacturing process of the display device 20 may be disposed in the groove H. In an embodiment, the sacrificial pattern SP may include a material having a higher crystallization temperature than that of a material included in an uppermost layer of each of the first, second, and third pixel electrodes PE1, PE2, and PE3 (e.g., the third layer of each of the first, second, and third pixel electrodes PE1, PE2, and PE3). For example, the sacrificial pattern SP may include a material having a crystallization temperature higher than a temperature at which a manufacturing process of the pixel defining layer PDL is performed, and the uppermost layer of each of the first, second, and third pixel electrodes PE1, PE2, and PE3 may include a material having a crystallization temperature lower than the temperature at which the manufacturing process of the pixel defining layer PDL is performed. In an embodiment, the sacrificial pattern SP may have an etching selectivity higher than that of the first, second, and third pixel electrodes PE1, PE2, and PE3 with respect to an etchant that may be used when patterning the sacrificial pattern SP. For example, the uppermost layer of each of the first, second, and third pixel electrodes PE1, PE2, and PE3 may include indium tin oxide, and the sacrificial pattern SP may include indium zinc oxide, but the present disclosure is not limited thereto.

However, the present disclosure is not limited thereto, and in another embodiment, the sacrificial pattern SP might not be disposed in the groove H. For example, the sacrificial pattern SP may be completely removed in the manufacturing process of the display device 20.

The intermediate layer ML, the common electrode CE, and the encapsulation layer TFE may be sequentially disposed on the first, second, and third pixel electrodes PE1, PE2, and PE3 and the first and second pixel defining layers PDL1 and PDL2.

In an embodiment, the intermediate layer ML may be disconnected by the first pixel defining layer PDL1. The intermediate layer ML may be disconnected by a shape of the first pixel defining layer PDL1, and may include a first portion disposed on the first, second, and third pixel electrodes PE1, PE2, and PE3 and the second pixel defining layer PDL2 and a second portion disposed on the first pixel defining layer PDL1 and spaced apart from the first portion. In some cases, the intermediate layer ML may cover upper surfaces of the first and second pixel electrodes PE1 and PE2. In some cases, the intermediate layer ML may cover the upper surface and side surfaces of the first and second pixel defining layers PDL1 and PDL2.

For example, the intermediate layer ML may be disconnected between relatively more adjacent light emitting elements (i.e., light emitting elements including pixel electrodes spaced apart from each other by the first distance D1). Accordingly, leakage current that may occur between the light emitting elements may be minimized, and color mixing between the light emitting elements may be minimized. For example, the intermediate layer ML may be disconnected between the first and second light emitting elements LE1 and LE2 including the first and second pixel electrodes PE1 and PE2 spaced apart from each other by the first distance D1, and might not be disconnected between the first and third light emitting elements LE1 and LE3 including the first and third pixel electrodes PEL and PE3 spaced apart from each other by the second distance D2. Accordingly, leakage current that may occur between the first and second light emitting elements LE1 and LE2 may be minimized to minimize color mixing between the first and second light emitting elements LE1 and LE2. For example, similar to the display device 10 in FIG. 3, the intermediate layer ML includes a first portion and a second portion. For example, the first portion and the second portion of the intermediate layer ML may be disconnected between the light emitting elements (e.g., the first light emitting element LE1 and the second light emitting element LE2).

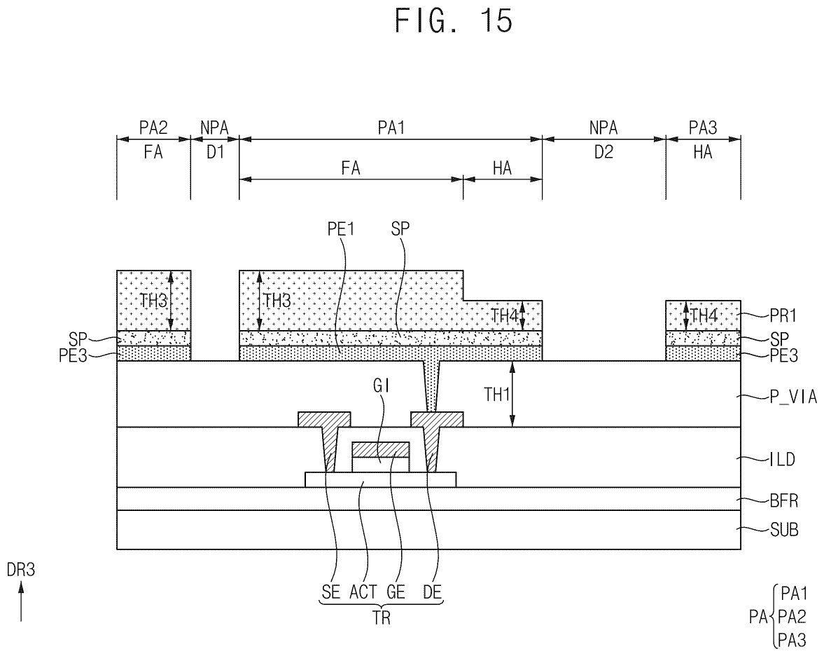

FIGS. 15, 16, 17, 18, and 19 are views illustrating a method for manufacturing a display device according to an embodiment of the present disclosure. A method of manufacturing a display device described with reference to FIGS. 15, 16, 17, 18, and 19 may be a method of manufacturing the display device 20 described with reference to FIGS. 13 and 14. Hereinafter, redundant descriptions may be omitted or simplified.

Referring to FIG. 15, the buffer layer BFR, the active pattern ACT, the gate insulating layer GI, the gate electrode GE, the interlayer insulating layer ILD, the first and second electrodes SE and DE, a preliminary via insulating layer P_VIA, the first, second, and third pixel electrodes PE1, PE2 and PE3, a sacrificial pattern SP, and a first photoresist pattern PR1 may be sequentially formed on the substrate SUB. In some embodiments, the active pattern ACT may be disposed on the buffer layer BFR to cover a portion of the buffer layer BFR. In some embodiments, contact holes may be formed through the interlayer insulating layer ILD, where the first and second electrodes SE and DE are placed in the contact holes.

The first, second, and third pixel electrodes PE1, PE2, and PE3, the sacrificial pattern SP, and the first photoresist pattern PR1 may be formed in the pixel electrode area PA, and might not be formed in the non-pixel electrode area NPA. For example, a pixel electrode layer, a sacrificial layer, and the first photoresist pattern PR1 may be sequentially formed on the preliminary via insulating layer P_VIA, and the pixel electrode layer and the sacrificial layer may be patterned using the first photoresist pattern PR1 to form the first, second, and third pixel electrodes PE1, PE2, and PE3 and the sacrificial pattern SP in the pixel electrode area PA, respectively. In some cases, a contact hole may be formed through the preliminary via insulating layer P_VIA, where the second pixel electrode PE2 extends into the contact hole and contacts the upper surface of the second electrode DE (or the first electrode SE) of the transistor TR.

Each of the first, second, and third pixel electrodes PE1, PE2, and PE3 may have a multi-layer structure. For example, each of the first, second, and third pixel electrodes PE1, PE2, and PE3 may include a first layer disposed on the preliminary via insulating layer P_VIA, a second layer disposed on the first layer, and a third layer disposed on the second layer.

In an embodiment, the sacrificial layer SL may include a material different from that of the first, second, and third pixel electrodes PE1, PE2, and PE3. For example, the sacrificial layer SL may include a material having a crystallization temperature higher than that of a material included in an uppermost layer of each of the first, second, and third pixel electrodes PE1, PE2, and PE3.

In an embodiment, a portion of the first photoresist pattern PR1 may be formed using a half-tone mask. For example, a photoresist layer may be formed on the sacrificial layer, and the photoresist layer may be patterned using a half-tone mask to form the first photoresist pattern PR1. For example, the portion of the first photoresist pattern PR1 formed using a half-tone mask may be disposed in the half-tone area HA of the pixel electrode areas.

The first photoresist pattern PR1 may define a full-tone area FA and a half-tone area HA in the pixel electrode area PA. The first photoresist pattern PR1 may have a third thickness TH3 in the third direction DR3 in the full-tone area FA, and may have a fourth thickness TH4 in the third direction DR3 in the half-tone area HA. The third thickness TH3 may be greater than the fourth thickness TH4.

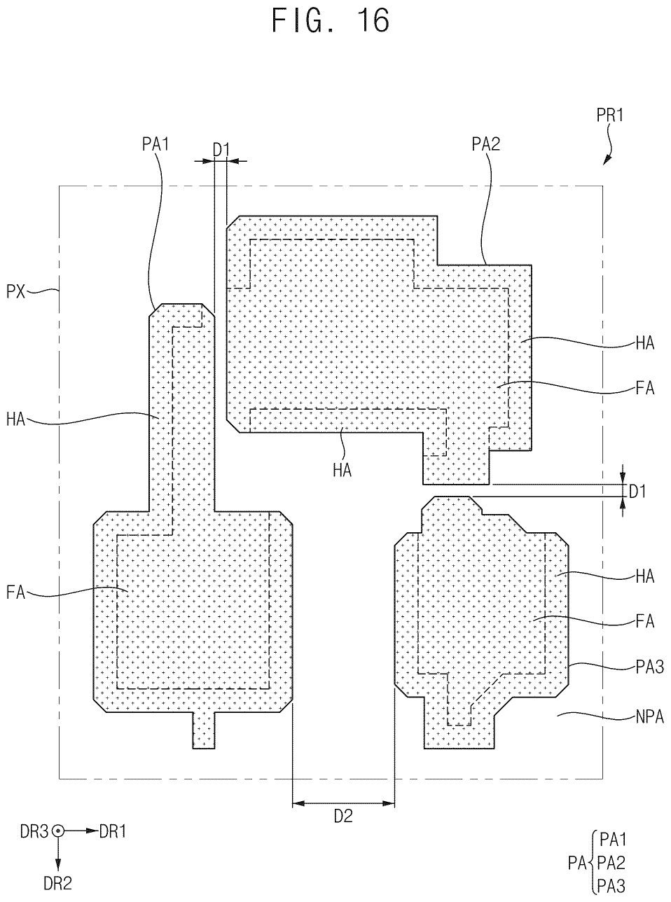

In an embodiment, the full-tone area FA may be adjacent to the non-pixel electrode area NPA of the first distance D1, and the half-tone area HA may be adjacent to the non-pixel electrode area NPA of the second distance D2. In the first, second, and third pixel electrode areas PA1, PA2, and PA3 adjacent to each other, an area spaced apart from each other by a relatively small distance (i.e., an area spaced apart by the first distance D1) may be the full-tone area FA, and an area spaced apart from each other by a relatively large distance (i.e., an area spaced apart by the second distance D2) may the half-tone area HA. For example, an edge of an area spaced apart by the second distance D2 among the first, second, and third pixel electrode areas PA1, PA2, and PA3 adjacent to each other may be the half-tone area HA, and a remaining area among the first, second, and third pixel electrode areas PA1, PA2, and PA3 may be the full-tone area FA (see FIGS. 13 and 16).

For example, the first photoresist pattern PR1 may have the fourth thickness TH4 at an end of an area spaced apart from each other by the second distance D2 among the first, second, and third pixel electrode areas PA1, PA2, and PA3 adjacent to each other, and may have the third thickness TH3 in a remaining area among the first, second, and third pixel electrode areas PA1, PA2, and PA3 adjacent to each other. For example, the first photoresist pattern PR1 may have the fourth thickness TH4 in an area adjacent to the non-pixel electrode area NPA having the second distance D2 among the first, second, and third pixel electrode areas PA1, PA2, and PA3, and may have the third thickness TH3 in a remaining area among the first, second, and third pixel electrode areas PA1, PA2, and PA3.

Referring to FIGS. 15, 17, and 18, a portion of the first photoresist pattern PR1 may be removed to form a second photoresist pattern PR2, and a portion of the preliminary via insulating layer P_VIA may be removed to form the via insulating layer VIA.

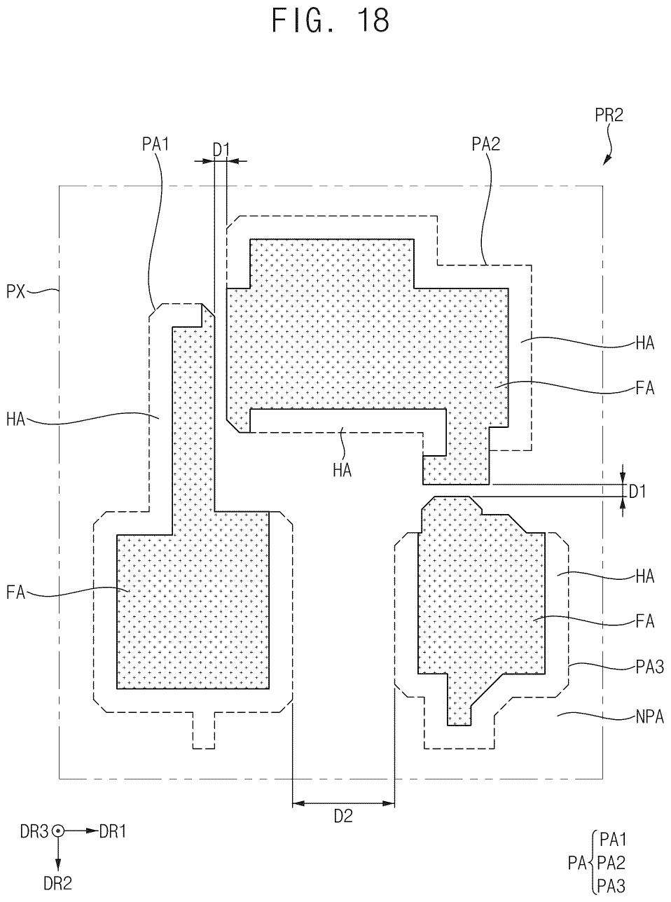

In an embodiment, the second photoresist pattern PR2 may be formed by removing the first photoresist pattern PR1 by at least a thickness of the first photoresist pattern PR1 in the half-tone area HA (i.e., the fourth thickness TH4). The first photoresist pattern PR1 in the half-tone area HA and a portion of the first photoresist pattern PR1 in the full-tone area FA may be removed to form the second photoresist pattern PR2 in the full-tone area FA (see FIG. 18). Accordingly, the sacrificial pattern SP may be exposed in the half-tone area HA. For example, the upper surface of the sacrificial pattern SP may be exposed in the half-tone area HA.

The second photoresist pattern PR2 may have a fifth thickness TH5 in the third direction DR3 in the full-tone area FA. The fifth thickness TH5 may be less than the third thickness TH3. For example, the fifth thickness TH5 may be a value obtained by subtracting the fourth thickness TH4 from the third thickness TH3.

The via insulating layer VIA may be formed by removing a portion of the preliminary via insulating layer P_VIA in the non-pixel electrode area NPA. For example, an upper surface of the preliminary via insulating layer P_VIA may be recessed in a direction opposite to the third direction DR3 in the non-pixel electrode area NPA to form the via insulating layer VIA having the first thickness TH1 in the pixel electrode area PA and the second thickness TH2 in the non-pixel electrode area NPA. In some embodiments, the preliminary via insulating layer P_VIA in the non-pixel electrode area NPA having the first distance D1 and the second distance D2 may be removed by the same amount of thickness (e.g., fourth thickness TH4) to form the via insulating layer VIA. In some cases, the difference between the first thickness TH1 and the second thickness TH2 may be the same or substantially the same as the fourth thickness TH4.

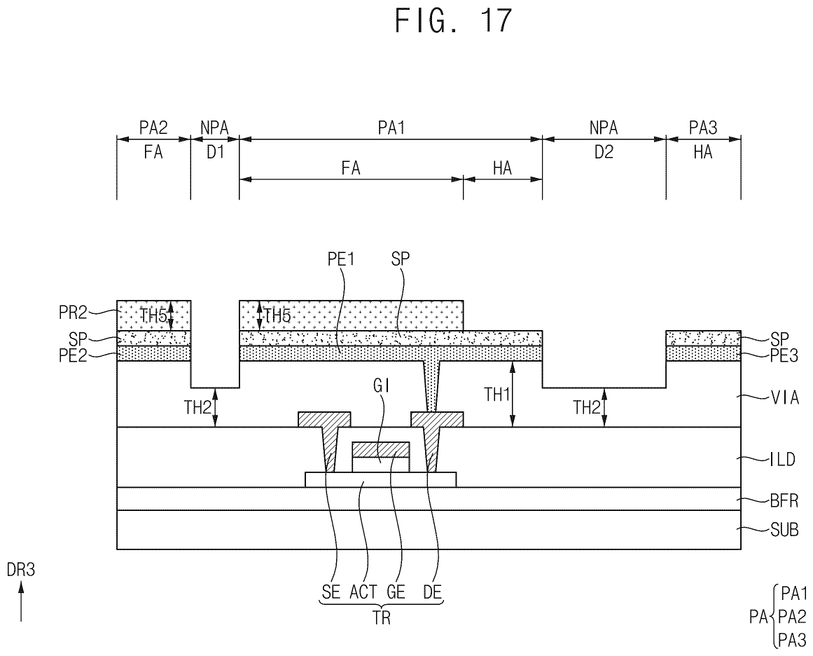

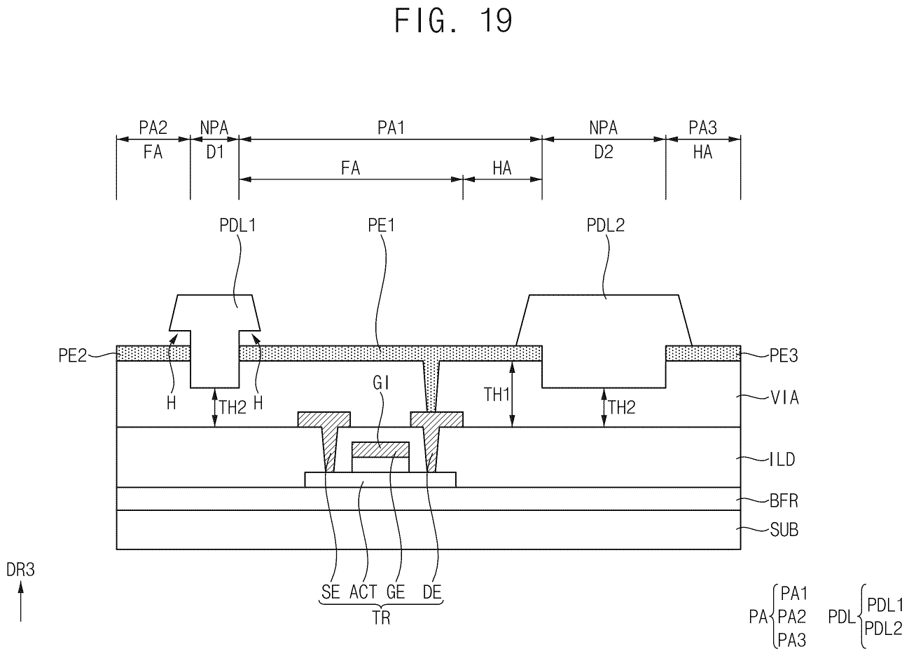

Referring to FIGS. 17 and 19, the sacrificial pattern SP may be patterned by using the second photoresist pattern PR2 so that the sacrificial pattern SP may be formed (i.e., remained) in the full-tone area FA. The sacrificial pattern SP exposed in the half-tone area HA may be removed so that the first, second, and third pixel electrodes PE1, PE2, and PE3 may be exposed in the half-tone area HA.

Thereafter, the second photoresist pattern PR2 may be removed to expose the sacrificial pattern SP in the full-tone area FA, and the pixel defining layer PDL may be formed on the via insulating layer VIA, the first, second, and third pixel electrodes PE1, PE2, and PE3, and the sacrificial pattern SP. In some cases, sacrificial pattern SP exposed in the half-tone area HA may be removed to expose upper surface of a portion of the first pixel electrode PE1 and the third pixel electrode PE3.

The pixel defining layer PDL may include the first pixel defining layer PDL1 and the second pixel defining layer PDL2. The first pixel defining layer PDL1 may be formed on the sacrificial pattern SP and on the via insulating layer VIA in the non-pixel electrode area NPA having the first distance D1, and the second pixel defining layer PDL2 may be formed on the via insulating layer VIA in the non-pixel electrode area NPA having the second distance D2. A portion of the first pixel defining layer PDL1 may be formed in the full-tone area FA to be in contact with an upper surface of the sacrificial pattern SP, and a portion of the second pixel defining layer PDL2 may be formed in the half-tone area HA to be in contact with an upper surface of each of the first, second, and third pixel electrodes PE1, PE2 and PE3. In some cases, a portion of the second pixel defining layer PDL2 may be formed in the half-tone area HA to be in contact with an upper surface of each of the first and third pixel electrodes PE1 and PE3. For example, a side surface of the first pixel defining layer PDL1 may cover the sacrificial pattern SP in the full-tone area FA, and a side surface of the second pixel defining layer PDL2 may cover the first, second, and third pixel electrodes PE1, PE2, and PE3 in the half-tone area HA.

Thereafter, the sacrificial pattern SP may be removed to form the groove H having a shape in which a portion of the side surface of the first pixel defining layer PDL1 is recessed. For example, etching selectivity of the sacrificial pattern SP may be higher than etching selectivity of the first, second, and third pixel electrodes PE1, PE2, and PE3 with respect to an etchant that may be used when removing the sacrificial pattern SP. For example, while the pixel defining layer PDL is formed, a material included in an uppermost layer of each of the first, second, and third pixel electrodes PE1, PE2, and PE3 may be crystallized, and a material included in the sacrificial pattern SP might not be crystallized. Accordingly, the sacrificial pattern SP may be more easily removed than the first, second, and third pixel electrodes PE1, PE2, and PE3.

As the sacrificial pattern SP covered by the side surface of the first pixel defining layer PDL1 is removed in the full-tone area FA, the first pixel defining layer PDL1 may be spaced apart from an upper surface of each of the first, second, and third pixel electrodes PE1, PE2 and PE3 in the third direction DR3. For example, the first pixel defining layer PDL1 may have an undercut shape in a cross-sectional view.

Although FIG. 19 illustrates that the sacrificial pattern SP is completely removed, the present disclosure is not limited thereto. In another embodiment, as illustrated in FIG. 14, the sacrificial pattern SP might not be completely removed, and a portion of the sacrificial pattern SP may remain in the groove H.

Referring back to FIG. 14, the intermediate layer ML may be formed on the first, second, and third pixel electrodes PE1, PE2, and PE3 and the pixel defining layer PDL. In an embodiment, the intermediate layer ML may be disconnected by a shape of the first pixel defining layer PDL1. The common electrode CE and the encapsulation layer TFE may be sequentially formed on the intermediate layer ML, and accordingly, the display device 20 illustrated in FIG. 14 may be manufactured. For example, the common electrode CE may be formed on the intermediate layer ML and covers the upper surface of the intermediate layer ML, the groove H, and a portion of the side surface of the first pixel defining layer PDL1. As a result, the intermediate layer ML may be disconnected by the common electrode CE. Accordingly, leakage current that may occur between the first, second, and third light emitting elements LE1, LE2, and LE3 adjacent to each other may be minimized, and thus color mixing between the first, second, and third light emitting elements LE1, LE2, and LE3 may be minimized. In some cases, the encapsulation layer TFE is formed on and covers the common electrode CE.

The display device 20 according to an embodiment of the present disclosure may include the first pixel defining layer PDL1 disposed on pixel electrodes spaced apart from each other by the first distance D1 among the first, second, and third pixel electrodes PE1, PE2, and PE3 adjacent to each other, and the second pixel defining layer PDL2 disposed on pixel electrodes spaced apart from each other by the second distance D2 among the first, second, and third pixel electrodes PE1, PE2, and PE3 adjacent to each other. The first pixel defining layer PDL1 may include the groove H, and the intermediate layer ML may be disconnected by the shape of the first pixel defining layer PDL1. Accordingly, leakage current that may occur between the first, second, and third light emitting elements LE1, LE2, and LE3 adjacent to each other may be minimized, and thus color mixing between the first, second, and third light emitting elements LE1, LE2, and LE3 may be minimized. In some cases, the shape of the first pixel defining layer PDL1 may be formed through the first photoresist pattern PR1 for patterning the first, second, and third pixel electrodes PE1, PE2, and PE3 formed using a half-tone mask, and thus a process using a separate mask for forming a structure that disconnects the intermediate layer ML might not be required.

The display devices 10 and 20 according to embodiments of the present disclosure may be applied to various electronic devices. An electronic device according to an embodiment of the present disclosure may include the display device 10 or the display device 20 described above, and may further include a module or device having additional functions in addition to the display device 10 or the display device 20.

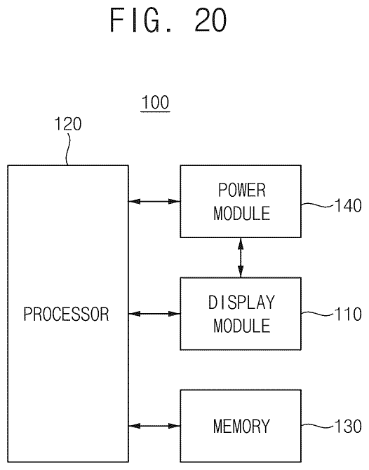

FIG. 20 is a block diagram illustrating an electronic device according to an embodiment of the present disclosure.

Referring to FIG. 20, an electronic device 100 may include a display module 110, a processor 120, a memory 130, and a power module 140.

The processor 120 may include at least one of a central processing unit (CPU), an application processor (AP), a graphic processing unit (GPU), a communication processor (CP), an image signal processor (ISP), and a controller.

The memory 130 may store data information necessary for an operation of the processor 120 or the display module 110. When the processor 120 executes an application stored in the memory 130, an image data signal and/or an input control signal may be transmitted to the display module 110, and the display module 110 may process the received signal and output image information through a display screen.

The power module 140 may include a power supply module such as a power adapter, a battery device, or the like and a power conversion module that converts power supplied by the power supply module to generate power necessary for an operation of the electronic device 100.

At least one of the components of the electronic device 100 described above may be included in the display device according to an embodiment described above. In addition, some of individual modules functionally included in one module may be included in the display device, and others may be provided separately from the display device. For example, the display device may include the display module 110, and the processor 120, the memory 130, and the power module 140 may be provided in form of other devices in the electronic device 100 other than the display device.

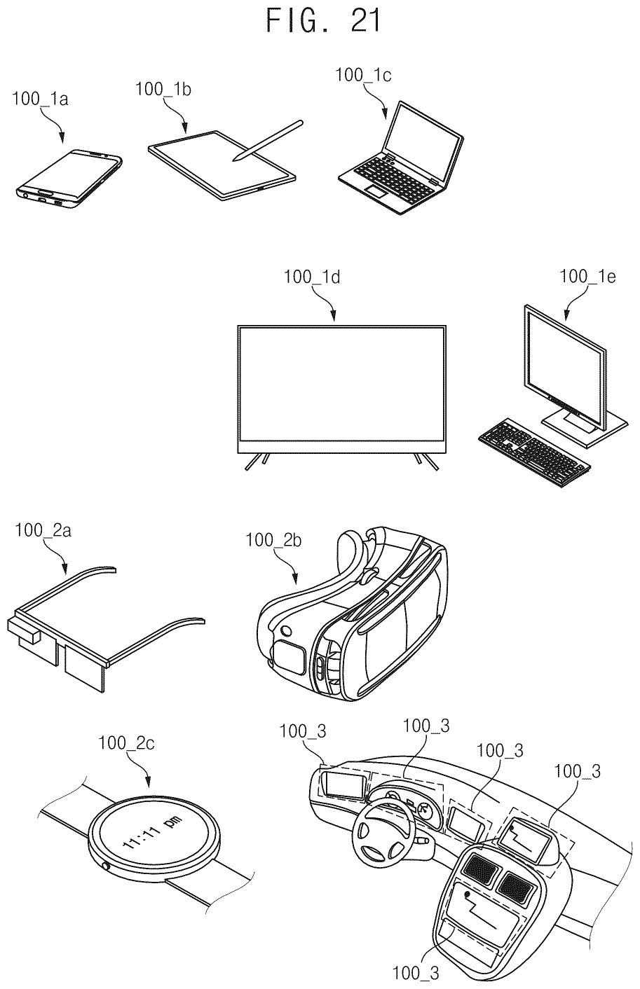

FIG. 21 is a schematic view illustrating electronic devices according to embodiments of the present disclosure.

Referring to FIG. 21, various electronic devices to which the display device according to an embodiment of the present disclosure is applied may include not only an image display electronic device, but also a wearable electronic device including a display module, a vehicle electronic device 100_3 including a display module, or the like. The image display electronic device may be a smartphone 100_1a, a tablet PC 100_1b, a laptop 100_1c, a TV 100_1d, a desk monitor 100_1e, or the like. The wearable electronic device may be smart glasses 100_2a, a head mounted display 100_2b, a smart watch 100_2c, or the like. The vehicle electronic device 100_3 may be a center information display (CID) disposed on a dashboard and center fascia of a vehicle, a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a via insulating layer disposed on a substrate;
a first light emitting element disposed on the via insulating layer, wherein the first light emitting element includes a first pixel electrode;
a second light emitting element disposed on the via insulating layer, wherein the second light emitting element includes a second pixel electrode, and wherein the second pixel electrode is spaced apart from the first pixel electrode by at least a first distance to form a first non-pixel electrode area having at least the first distance;
a third light emitting element disposed on the via insulating layer, wherein the third light emitting element includes a third pixel electrode, and wherein the third pixel electrode is spaced apart from the first pixel electrode by a second distance to form a second non-pixel electrode area having at least the second distance;
a first pixel defining layer disposed in the first non-pixel electrode area on the via insulating layer; and
a second pixel defining layer disposed in the second non-pixel electrode area on the via insulating layer, wherein the second pixel defining layer has a cross-sectional shape different from a cross-sectional shape of the first pixel defining layer.

2. The display device of claim 1, wherein the second distance is greater than or equal to the first distance.

3. The display device of claim 1, wherein the first pixel defining layer includes a groove between a lower surface of the first pixel defining layer and an upper surface of each of the first pixel electrode and the second pixel electrode.

4. The display device of claim 3, further comprising:
a sacrificial pattern disposed in the groove.

5. The display device of claim 1, wherein:
an upper portion of the first pixel defining layer is spaced apart from an upper surface of the first pixel electrode and an upper surface of the second pixel electrode, and
an upper portion of the second pixel defining layer is in contact with the upper surface of the first pixel electrode and an upper surface of the third pixel electrode.

6. The display device of claim 1, wherein each of the first light emitting element, the second light emitting element, and the third light emitting element further includes:
an intermediate layer disposed on the first pixel defining layer or the second pixel defining layer, wherein the intermediate layer includes a charge generation layer, and
wherein a first portion of the intermediate layer and a second portion of the intermediate layer are disconnected by the first pixel defining layer.

7. The display device of claim 1, wherein an upper surface of the via insulating layer is recessed toward a lower surface of the via insulating layer in the first non-pixel electrode area and the second non-pixel electrode area.

8. A method of manufacturing a display device, the method comprising:
forming a preliminary via insulating layer on a substrate;
forming a first pixel electrode, a second pixel electrode, and a third pixel electrode on the preliminary via insulating layer, wherein the second pixel electrode is spaced apart from the first pixel electrode by at least a first distance to form a first non-pixel electrode area having at least the first distance, and wherein the third pixel electrode is spaced apart from the first pixel electrode by a second distance to form a second non-pixel electrode area having at least the second distance;
forming a first pixel defining layer in the first non-pixel electrode area; and
forming a second pixel defining layer in the second non-pixel electrode area, wherein the second pixel defining layer has a cross-sectional shape different from a cross-sectional shape of the first pixel defining layer.

9. The method of claim 8, wherein the second distance is greater than or equal to the first distance.

10. The method of claim 8, wherein the forming of the first pixel electrode, the second pixel electrode, and the third pixel electrode includes:
forming a pixel electrode layer on the preliminary via insulating layer;
forming a sacrificial layer on the pixel electrode layer;
forming a first photoresist pattern on the sacrificial layer; and
patterning the pixel electrode layer and the sacrificial layer using the first photoresist pattern to form the first pixel electrode, the second pixel electrode, the third pixel electrode, and a sacrificial pattern.

11. The method of claim 10, wherein the forming of the first photoresist pattern includes:
forming a full-tone area of the first photoresist pattern to have a first thickness; and
forming a half-tone area of the first photoresist pattern to have a second thickness,
wherein an area adjacent to the first non-pixel electrode area is the full-tone area, and an area adjacent to the second non-pixel electrode area is the half-tone area.

12. The method of claim 11, further comprising:
removing the first photoresist pattern at least by the second thickness to form a second photoresist pattern in the full-tone area;
removing at least a portion of the preliminary via insulating layer in the first non-pixel electrode area and the second non-pixel electrode area to form a via insulating layer; and
removing a portion of the sacrificial pattern in the half-tone area using the second photoresist pattern.

13. The method of claim 12, wherein:
the first pixel defining layer is in contact with an upper surface of the sacrificial pattern in the full-tone area, and
the second pixel defining layer is in contact with a portion of an upper surface of the first pixel electrode and a portion of an upper surface of the third pixel electrode in the half-tone area.

14. The method of claim 8, further comprising:
forming an intermediate layer on the first pixel defining layer and the second pixel defining layer,
wherein a first portion of the intermediate layer and a second portion of the intermediate layer are disconnected by the first pixel defining layer.

15. An electronic device comprising:
a display device, wherein the display device comprises:
a via insulating layer disposed on a substrate;
a first light emitting element disposed on the via insulating layer, wherein the first light emitting element includes a first pixel electrode;
a second light emitting element disposed on the via insulating layer, wherein the second light emitting element includes a second pixel electrode, and wherein the second pixel electrode is spaced apart from the first pixel electrode by at least a first distance to form a first non-pixel electrode area having at least the first distance;
a third light emitting element disposed on the via insulating layer, wherein the third light emitting element includes a third pixel electrode, and wherein the third pixel electrode is spaced apart from the first pixel electrode by a second distance to form a second non-pixel electrode area having at least the second distance;
a first pixel defining layer disposed in the first non-pixel electrode area on the via insulating layer; and
a second pixel defining layer disposed in the second non-pixel electrode area on the via insulating layer, wherein the second pixel defining layer has a cross-sectional shape different from a cross-sectional shape of the first pixel defining layer.

16. The electronic device of claim 15, wherein the second distance is greater than or equal to the first distance.

17. The electronic device of claim 15, wherein the first pixel defining layer includes a groove between a lower surface of the first pixel defining layer and an upper surface of each of the first pixel electrode and the second pixel electrode.

18. The electronic device of claim 15, wherein:
an upper portion of the first pixel defining layer is spaced apart from an upper surface of the first pixel electrode and an upper surface of the second pixel electrode, and
an upper portion of the second pixel defining layer is in contact with the upper surface of the first pixel electrode and an upper surface of the third pixel electrode.

19. The electronic device of claim 15, wherein each of the first light emitting element, the second light emitting element, and the third light emitting element further includes:
an intermediate layer disposed on the first pixel defining layer or the second pixel defining layer, wherein the intermediate layer includes a charge generation layer.

20. The electronic device of claim 19, wherein a first portion of the intermediate layer and a second portion of the intermediate layer are disconnected by the first pixel defining layer.
